(19) United States
(12) Patent Application Publication
(10) Pub. No.: US 2025/0308900 A1
(43) Pub. Date: Oct. 2, 2025

(54) SITU PROTECTIVE POLYMER VIA MILLING-EXCITATION

(71) Applicant: FEI Company, Hillsboro, OR (US)

(72) Inventors: George Demetrios Papasouliotis, Lake Oswego, OR (US); Derek Elwin Neben, Portland, OR (US)

(21) Appl. No.: 18/624,852

(22) Filed: Apr. 2, 2024

(51) Int. Cl. H01L 21/263; H01J 37/305; H01L 21/02

(52) U.S. Cl. CPC H01L 21/2633; H01J 37/3053; H01L 21/02057; H01J 2237/006; H01J 2237/31749

(57) ABSTRACT

Systems or techniques are provided for facilitating in situ protective polymer via milling-excitation. In various embodiments, a device can comprise an ion beam emitter that can be configured to perform milling of a cutface of a specimen via an ion beam. In various aspects, the device can comprise a gas injector that can be configured to deliver a decomposed precursor to the cutface. In various instances, the ion beam can polymerize the decomposed precursor, thereby growing a polymer shield layer on the cutface during the milling.

### BACKGROUND

Various scientific instruments can perform milling on specimens. Creating high aspect ratio structures via such milling can be non-trivial.

### SUMMARY

The following presents a summary to provide a basic understanding of one or more embodiments. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus or computer program products that facilitate in situ protective polymer via milling excitation are described.

According to one or more embodiments, a device is provided. In various aspects, the device can comprise an ion beam emitter that can be configured to perform milling of a cutface of a specimen via an ion beam. In various instances, the device can comprise a gas injector that can be configured to deliver a decomposed precursor to the cutface. In various cases, the ion beam can polymerize the decomposed precursor, thereby growing a polymer shield layer on the cutface during the milling.

According to one or more embodiments, a method is provided. In various embodiments, the method can comprise milling, by an ion beam emitter, a cutface of a specimen via an ion beam. In various aspects, the method can comprise delivering, by a gas injector, a decomposed precursor to the cutface. In various instances, the ion beam can polymerize the decomposed precursor, thereby growing a polymer shield layer on the cutface during the milling.

According to one or more embodiments, a scientific instrument is provided. In various aspects, the scientific instrument can comprise a focused ion beam (FIB) system that can be configured to mill a lamella. In various instances, the scientific instrument can comprise a gas injector system that can be configured to grow a polymer passivation layer on the lamella simultaneously as the FIB system mills the lamella. In various cases, the polymer passivation layer can protect vertical sidewalls of the lamella from milling.

### DESCRIPTION OF THE DRAWINGS

Various embodiments will be readily understood by the following detailed description in conjunction with the accompanying figures. To facilitate this description, like reference numerals designate like structural elements. Embodiments are illustrated by way of example, not by way of limitation, in the figures. The figures are not necessarily drawn to scale.

FIG. 1 illustrates an example, non-limiting block diagram of a scientific instrument module in accordance with various embodiments described herein.

FIG. 2 illustrates an example, non-limiting flow diagram of a computer-implemented method in accordance with various embodiments described herein.

FIGS. 3-4 illustrate example, non-limiting block diagrams of a dual beam microscope in accordance with one or more embodiments described herein.

FIG. 5 illustrates a block diagram of an example, non-limiting system that facilitates in situ protective polymers via milling-excitation in accordance with one or more embodiments described herein.

FIGS. 6-12 illustrate example, non-limiting block diagrams showing how a protective polymer layer can be grown during milling in accordance with one or more embodiments described herein.

FIGS. 13-15 illustrate example, non-limiting block diagrams showing various precursor delivery techniques for growing a protective polymer layer during milling in accordance with one or more embodiments described herein.

FIG. 16 illustrates an example, non-limiting block diagram showing how an electron beam can be used in conjunction with a focused ion beam to grow a protective polymer layer during milling in accordance with one or more embodiments described herein.

FIGS. 17-19 illustrate example, non-limiting experimental results in accordance with one or more embodiments described herein.

FIG. 20 illustrates an example, non-limiting block diagram of a graphical user interface that can be used in the performance of some or all of the methods or techniques disclosed herein, in accordance with various embodiments described herein.

FIG. 21 illustrates an example, non-limiting block diagram of a computing device that can perform some or all of the methods or techniques disclosed herein, in accordance with various embodiments described herein.

FIG. 22 illustrates an example, non-limiting block diagram of a scientific instrument support system in which some or all of the methods or techniques disclosed herein may be performed, in accordance with various embodiments described herein.

FIG. 23 illustrates a block diagram of an example, non-limiting operating environment in which one or more embodiments described herein can be facilitated.

FIG. 24 illustrates an example networking environment operable to execute various implementations described herein.

### DETAILED DESCRIPTION

The following detailed description is merely illustrative and is not intended to limit embodiments or application/uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiments. Various additional operations can be performed, or described operations can be omitted in additional embodiments.

Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices. As used herein, the phrase “based on” should be understood to mean “based at least in part on,” unless otherwise specified.

A scientific instrument (e.g., mass spectrometer, charged-particle microscope) can be any suitable computerized device that can capture or generate electronic measurements in a scientific, laboratory, research, or clinical operational context (e.g., that can capture or generate spectroscopic images or composition spectra). To facilitate the capture or generation of such electronic measurements, scientific instruments can leverage complex arrangements of actuatable parts (e.g., ion sources, electron sources, lenses, heaters, coolers, fluid valves, fluid pumps, circuit switches, specimen stages, apertures), sensors (e.g., electron detectors, voltmeters, thermistors, potentiometers, pressure gauges), or consumables (e.g., carrier fluids, calibrants, filters).

Various scientific instruments (e.g., dual beam charged-particle microscopes) can utilize their constituent actuatable parts to mill specimens (e.g., to sputter or remove material from targeted locations of specimens via focused ion beams). In various aspects, it can be desired to utilize such milling to create high aspect ratio structures on, or to extract high aspect ratio structures from, such specimens. In various instances, aspect ratio can refer to the ratio of a structure's height to its width or thickness. So, a high aspect ratio structure can be a structure that is much taller than it is wide or thick (e.g., a high aspect ratio structure can be one or more orders of magnitude taller than it is wide or thick). For example, a lamella that is cut from a specimen can be considered as a high aspect ratio structure (e.g., a lamella can be a rectangular prism that is sliced from a specimen and whose thickness can be several orders of magnitude smaller than its other two dimensions). As another example, a through-silicon via (TSV) that is formed in a specimen can be considered as a high aspect ratio structure (e.g., a TSV can be a tunnel that couples one plane of a silicon specimen to another plane of the silicon specimen, and the cross-sectional dimensions of the TSV can be several orders of magnitude smaller than its length).

However, creating or extracting a high aspect ratio structure by milling (or by any other photolithography techniques) can be a non-trivial task. In particular, as the aspect ratio of a given structure rises, the sidewalls of that structure (e.g., walls of that structure that are vertical or otherwise parallel to the direction or axis of milling) can become progressively more likely to suffer damage. Indeed, the sidewalls of a high aspect ratio structure can be vulnerable to chemical or kinetic interaction by the beam tails of a focused ion beam, which can cause damage such as curtaining, erosion, or clipping to the sidewalls.

Some existing techniques attempt to prevent or reduce sidewall damage via the implementation of hard masks, such as tungsten caps or other photoresist layers, that resist milling (e.g., that are not significantly affected by a focused ion beam). In particular, such existing techniques can involve forming a hard mask overtop of a specimen, such that the hard mask is normal to the direction of milling and has an opening above whatever area of that specimen that is desired to be milled to form or extract a high aspect ratio structure. Because the hard mask resists milling, whatever portions of the specimen that are beneath the hard mask can be at least partially protected from milling, whereas whatever portions of the specimen that are not beneath the hard mask can be removed or otherwise affected via milling.

Unfortunately, such existing techniques suffer from various disadvantages. Specifically, such existing techniques can be effort-intensive because they can require precise or accurate formation of the hard mask (e.g., if the hard mask is too big such that it is formed on unnecessary portions of the specimen, those unnecessary portions of the specimen can be at risk of damage from hard mask formation or from subsequent hard mask removal). Moreover, such existing techniques protect sidewalls only indirectly and thus are vulnerable to undercutting. For example, such undercutting can result in reverse taper trenches, which can be undesirable.

Other existing techniques attempt to prevent or reduce sidewall damage via the implementation of cyclically-deposited passivation films. Specifically, consider the Bosch process. The Bosch process is a technique for forming high aspect ratio structures (via etching rather than milling) that cycles through three consecutive or sequential steps. The first step of the Bosch process is to deposit a polymer passivation film onto the specimen. This is accomplished by using temperature-driven or plasma-driven chemical vapor deposition (e.g., by delivering precursors to the specimen and by using heat or plasma to cause those precursors to undergo a polymerization chemical reaction on the surface of the specimen). The second step of the Bosch process is to remove the polymer passivation film from a desired portion of the surface of the specimen, while leaving the remainder of the polymer passivation film in place; that is, while leaving the polymer passivation film on the sidewalls of the specimen. This is accomplished via any suitable polymer-selective etching technique. The third step of the Bosch process is to remove at least some amount of whatever portion of the specimen was revealed or uncovered during the second step. This is accomplished via any suitable specimen-selective etching technique, such as etching via SF₆ gas. Because the sidewalls of the specimen can remain covered by the polymer passivation film during the second step, the sidewalls can be protected from etching-related damage during the third step. These three steps are then repeated or cycled until a trench or structure of desired depth is etched into the specimen.

Unfortunately, such other existing techniques suffer from various disadvantages. Specifically, such other existing techniques can be time-consuming. Indeed, each three-step cycle of the Bosch process can remove a small amount of the specimen, and so very many of such three-step cycles can be needed to form high aspect ratio structures on the specimen. Furthermore, the Bosch process suffers from a phenomenon known as scalloping, which can cause the sidewalls of the specimen to undulate undesirably. The severity of such scalloping can be reduced by diminishing the amount of time spent in the third step of each three-step cycle. However, this commensurately reduces the etch rate of (e.g., the amount of material that is removed from the specimen during) each three-step cycle, and thus many more three-step cycles can be needed to form a high aspect ratio structure on or from the specimen. Because the amounts of time spent during the first and second steps of each three-step cycle can remain unchanged despite the time spent during the third step being reduced, the total amount of time consumed by performing all of such many more three-step cycles can be far greater than it otherwise would have been. In other words, when such other existing techniques are implemented, scalloping can be reduced only by drastically lengthening the already-considerable total amount of time spent performing such other existing techniques.

Accordingly, systems or techniques that can ameliorate one or more of these technical problems can be desirable.

Various embodiments described herein can address one or more of these technical problems. One or more embodiments described herein can include systems, computer-implemented methods, apparatus, or computer program products that can facilitate in situ protective polymers via milling-excitation. In other words, various embodiments described herein can facilitate the creation, formation, or extraction of high aspect ratio structures on or from specimens, by utilizing polymer passivation layers or films that are formed during (rather than before) milling. As mentioned above, some existing techniques do not utilize passivation layers at all, which can expose specimen sidewalls to unacceptably high risks of damage or erosion. As also mentioned above, other existing techniques (e.g., the Bosch process) use cyclically-deposited polymer passivation layers to prevent damage or erosion to specimen sidewalls. However, such other existing techniques consume excessive amounts of time and cause sidewall scalloping. Fortunately, the inventors of various embodiments described herein devised how to leverage polymer passivation layers to protect specimen sidewalls, without suffering from the excessive time-consumption or from the scalloping of existing techniques.

In particular, the present inventors realized that, in the context of focused ion beam milling, the polymerization reaction that creates a polymer passivation layer on a specimen can be initiated, triggered, or otherwise caused by whatever focused ion beam is milling the specimen. In other words, the present inventors realized that the focused ion beam can be leveraged to accomplish two objectives simultaneously: to mill the specimen; and to trigger passivation layer polymerization while milling the specimen. More specifically, a focused ion beam can mill (e.g., can sputter or otherwise kinetically remove material from) the specimen. When appropriate precursors are present on or near the surface of the specimen, those precursors can, upon being exposed to the focused ion beam that is milling the specimen, become excited. Such excitation can initiate, trigger, or otherwise cause the precursors to polymerize on the specimen, thereby forming the polymer passivation layer. Now, although the polymer passivation layer can be resistant to specimen-selective etching, the polymer passivation layer can be not resistant to milling. So, whatever portions of the polymer passivation layer that are impacted or bombarded by the focused ion beam can be removed by the focused ion beam. However, unlike specimen-selective etching which can be considered as an isotropic, chemical removal process, milling can be considered as an anisotropic, physical removal process that removes more material (e.g., that has a higher sputter yield) from surfaces that are more normal or orthogonal to the direction or axis of the focused ion beam and that removes less material (e.g., that has a lower sputter yield) from surfaces that are more parallel to the direction or axis of the focused ion beam (e.g., that is, from sidewalls of the specimen).

Thus, the present inventors realized that the following can occur: the focused ion beam can cause the polymer passivation layer to grow at some given rate on normal surfaces of the specimen and on sidewalls of the specimen; while the polymer passivation layer is growing, the focused ion beam can physically or kinetically sputter atoms (e.g., polymer atoms or specimen atoms) from normal surfaces at a rate that is greater than the rate of growth of the polymer passivation layer; and, while the polymer passivation layer is growing, the focused ion beam can physically or kinetically sputter atoms (e.g., polymer atoms or specimen atoms) from sidewalls at a rate that is lesser than the rate of growth of the polymer passivation layer. Accordingly, the focused ion beam can cause a net removal of material from the normal surfaces of the specimen but can fail to cause a net removal of material from the sidewalls of the specimen. Indeed, if fresh precursors are continuously, continually, or otherwise regularly supplied to the specimen during milling, the polymer passivation layer can be considered as being continuously, continually, or regularly grown or replenished on the sidewalls by the focused ion beam, such that any curtaining, erosion, or clipping that the focused ion beam would have inflicted on the sidewalls is instead inflicted on the polymer passivation layer that covers the sidewalls. In other words, the beam tails of the focused ion beam can cause some amount of damage, erosion, clipping, or curtaining to the polymer passivation layer that covers the sidewalls rather than to the sidewalls itself, and such damage, erosion, clipping, or curtaining can be undone by newly-supplied precursors that are polymerized by the focused ion beam. In this way, the sidewalls can be safeguarded while the normal surfaces are milled to any desired depth. Moreover, because various embodiments described herein involve polymer passivation layer growth being conducted in parallel with material removal, various embodiments described herein can consume far less time than various existing techniques (such as the Bosch process which instead requires polymer deposition and material removal to be serially, consecutively, or sequentially performed). Furthermore, because various embodiments described herein involve the anisotropic, physical removal process of milling rather than the isotropic, chemical removal process of specimen-selective etching, various embodiments described herein can experience no (or otherwise severely reduced) scalloping. Further still, the polymer passivation layer can be easily removable via any suitable polymer-selective etchant, and so the polymer passivation layer need not be carefully, painstakingly, or otherwise precisely formed, unlike hard masks or tungsten caps.

Various embodiments described herein can be considered as a computerized tool (e.g., any suitable combination of computer-executable hardware or computer-executable software) that can facilitate in situ protective polymers via milling-excitation. In various aspects, such computerized tool can comprise an access component, a beam component, a gas component, or an etch component.

In various embodiments, there can be a scientific instrument. In various aspects, the scientific instrument can be any suitable computerized device that can perform or facilitate milling of any suitable specimen. As a non-limiting example, the scientific instrument can be a dual beam microscope that can facilitate milling via any suitable focused ion beam emitter and that can facilitate imaging or image-capture via any suitable electron beam emitter. In various instances, the scientific instrument can further comprise a gas injector. In various cases, the gas injector can deliver or otherwise transport (e.g., via atomization or spraying) any suitable reactive gas (e.g., an organic fluoride gas) to the specimen. In various aspects, the scientific instrument can further comprise an etcher. In various instances, the etcher can deliver or otherwise transport (e.g., by hydraulic pumping or spraying) any suitable dry or wet etchant (e.g., piranha solution) to the specimen.

In various cases, the specimen can exhibit any suitable architecture, construction, or composition. As a non-limiting example, the specimen can be a bare silicon substrate. As another non-limiting example, the specimen can be any suitable silicon substrate on which any suitable conductors or micro-circuitry components (e.g., transistor fin, transistor gate, transistor source drain) have been manufactured or fabricated via any suitable photolithography techniques. In various aspects, the specimen can be considered as having a cutface. In various cases, the cutface can be a surface of the specimen (e.g., a front surface, a rear surface) or a portion thereof from which material can be or has been milled, sputtered, ejected, or otherwise removed by operation of the focused ion beam emitter. Accordingly, the cutface can be considered as a cross-section (or a partial cross-section) of the specimen that is, has been, or will be revealed via milling. Note that the performance of more, additional, or follow-on milling can be considered as causing the cutface to move deeper into the specimen. In various cases, the specimen can contain different structures of interest at different depths, and so different ones of those structures of interest can be visible in or on the cutface, depending upon the depth of the cutface (e.g., depending upon how much total or cumulative milling is or has been performed on the specimen).

In various aspects, it can be desired to manufacture on the specimen, or to extract or cut from the specimen, a high aspect ratio structure via milling. Non-limiting examples of the high aspect ratio structure can include a lamella or a TSV. In any case, the computerized tool can cause the high aspect ratio structure to be manufactured, extracted, or cut as described herein.

In various embodiments, the access component of the computerized tool can electronically access the scientific instrument. For instance, the access component can transmit electronic instructions or commands to or can receive electronic data from the scientific instrument. Accordingly, the access component can be considered as a conduit through which other components of the computerized tool can electronically interact with (e.g., activate, deactivate, manipulate) the scientific instrument.

In various embodiments, the beam component of the computerized tool can electronically control the focused ion beam emitter of the scientific instrument. That is, the beam component can instruct (e.g., through the access component) the scientific instrument to activate, deactivate, reorient, or otherwise adjust the focused ion beam emitter in any suitable fashion. Accordingly, the beam component can control, manage, or otherwise govern what locations of the specimen are milled by the focused ion beam emitter, when such milling begins or ends, or how intensely the focused ion beam emitter performs such milling.

In various embodiments, the beam component of the computerized tool can also electronically control the electron beam emitter of the scientific instrument. That is, the beam component can instruct the scientific instrument to activate, deactivate, reorient, or otherwise adjust the electron beam emitter in any suitable fashion. Accordingly, the beam component can control, manage, or otherwise govern what locations of the specimen are imaged by the electron beam emitter, when such imaging occurs, or visual characteristics of such imaging (e.g., focal spot size, zoom level, contrast level).

In various embodiments, the gas component of the computerized tool can electronically control the gas injector of the scientific instrument. That is, the gas component can instruct the scientific instrument to activate, deactivate, reorient, or otherwise adjust the gas injector in any suitable fashion. Accordingly, the gas component can control, manage, or otherwise govern what volumes or concentrations of any suitable gases the specimen is exposed to or when such exposure begins or ends.

In various embodiments, the etch component of the computerized tool can electronically control the etcher of the scientific instrument. That is, the etch component can instruct the scientific instrument to activate, deactivate, reorient, or otherwise adjust the etcher in any suitable fashion. Accordingly, the etch component can control, manage, or otherwise govern a volume or concentration of etchant that the specimen is exposed to or when such exposure begins or ends.

Now, in various aspects, the gas component can command or otherwise cause the gas injector to deliver any suitable volume or concentration of a decomposed precursor to the specimen. In some instances, such delivery can occur continuously, continually, periodically, or otherwise regularly. In any case, such delivery can cause the decomposed precursor to be physically present on or otherwise physically adjacent to the cutface of the specimen. In various aspects, as described herein, the decomposed precursor can be reactive neutrals or reactive ions that are formed from the decomposition or breakdown of any suitable reactive gas. In some instances, the reactive gas can be any suitable organic fluoride gas, such as C₄F₈.

In various cases, the beam component can command or otherwise cause the focused ion beam emitter to bombard the cutface of the specimen with a focused ion beam having any suitable characteristics (e.g., any suitable ion beam composition such as gallium ions or xenon ions; any suitable ion electrode voltage or ion electrode current). In various aspects, the focused ion beam can strike the cutface of the specimen. Because the decomposed precursor can be physically on or adjacent to the cutface of the specimen, the decomposed precursor can be considered as being exposed to the focused ion beam. In various instances, such exposure can excite or otherwise provide energy to the decomposed precursor. Such excitation or energy provision can cause the decomposed precursor to undergo a polymerization reaction on the cutface of the specimen. In various cases, such polymerization reaction can cause the decomposed precursors to bond together into polymer chains that attach or latch onto the cutface of the specimen. Such polymer chains can collectively be considered as a polymerization passivation layer (also referred to as a polymer shield layer). In other words, the focused ion beam can cause the decomposed precursor to undergo a polymerization reaction, thereby causing the polymer passivation layer to grow on the cutface of the specimen.

In various aspects, the polymer passivation layer can grow on all of the surfaces of the cutface that are physically exposed to both the focused ion beam and the decomposed precursor. In various instances, some of such surfaces can be more normal or orthogonal to the direction or axis of the focused ion beam. These can be called floors of the cutface. In various cases, others of such surfaces can be more parallel to the direction or axis of the focused ion beam. These can be called sidewalls of the cutface. In various aspects, yet others of such surfaces can be at any suitable intermediate orientations with respect to the direction or axis of the focused ion beam. In any case, the polymer passivation layer can grow on the floors and sidewalls (and other surfaces) of the cutface.

Now, in various aspects, when the focused ion beam strikes or bombards any given layer of material, the focused ion beam can sputter or otherwise kinetically eject at least some atoms from that given layer of material, and the number of atoms that are sputtered or ejected in such fashion can depend upon how that given layer of material is oriented with respect to the focused ion beam. In particular, the focused ion beam can sputter or eject a larger number of atoms from the given layer of material is the given layer of material is more normal or orthogonal to the direction or axis of the focused ion beam. In contrast, the focused ion beam can sputter or eject a smaller number of atoms from the given layer of material if the given layer of material is more parallel to the direction or axis of the focused ion beam. Accordingly, the focused ion beam can be considered as sputtering or ejecting atoms at a significantly greater rate from the floors of the cutface than from the sidewalls of the cutface. Thus, the following can occur: the focused ion beam can sputter or eject atoms from whatever materials are on the floors of the cutface more quickly than the rate at which the polymer passivation layer can grow on the floors of the cutface; and the focused ion beam can sputter or eject atoms from whatever materials are on the sidewalls of the cutface less quickly than the rate at which the polymer passivation layer can grow on the sidewalls of the cutface. So, whatever amount of the polymer passivation layer that has already grown on the floors of the cutface can be eliminated by the focused ion beam, and, at such point, the focused ion beam can begin removing atoms from the floors of the cutface themselves. That is, the focused ion beam can mill or dig into the floors of the cutface despite the polymer passivation layer. Conversely, whatever amount of the polymer passivation layer that has already grown on the sidewalls of the cutface can continue to grow (e.g., until any suitable milling-growth equilibrium is achieved), and so the focused ion beam can be unable to begin removing atoms from the sidewalls of the cutface themselves. That is, the focused ion beam (or beam tails thereof) can be unable to mill, dig into, or otherwise damage the sidewalls of the cutface because of the polymer passivation layer. Note that the polymer passivation layer that grows on the sidewalls can be considered as protecting the sidewalls not just from the focused ion beam, but also from errant ions of the focused ion beam that strike the floors of the cutface and that then ricochet or rebound off the floors and into the sidewalls at steep angles (e.g., near lower or deeper portions of the sidewalls) or at glancing angles (e.g., near higher or top-level portions of the sidewalls).

In any case, when the cutface is exposed to both the focused ion beam and the decomposed precursor, the focused ion beam can be considered as both removing material from the floors of the cutface and simultaneously triggering polymerization on the sidewalls of the cutface. This can allow the floors of the cutface to be milled or dug quite deeply in an efficient or non-time-consuming manner, without causing much (if any) damage, clipping, erosion, or curtaining to the sidewalls of the cutface. In other words, this can allow any suitable high aspect ratio structure (e.g., with aspect ratios in excess of 50) to be fabricated on or extracted or cut from the cutface of the specimen by the focused ion beam with little to no sidewall damage.

In various aspects, once the floors of the cutface are milled or dug to any suitable desired depth (e.g., once whatever desired high aspect ratio structure is fabricated on or extracted from the cutface), the beam component can command the focused ion beam emitter to cease striking or bombarding the cutface with the focused ion beam, and the gas component can command the gas injector to cease delivering the decomposed precursor to the cutface. Note that, at such point in time, the polymer passivation layer can remain on the sidewalls of the cutface (e.g., on the sidewalls of whatever desired high aspect ratio structure is fabricated on or extracted from the cutface). In various instances, the etch component can respond by commanding or otherwise causing the etcher to bathe or douse the cutface (or whatever desired high aspect ratio structure is fabricated on or extracted from the cutface) in any suitable etchant that can be selectively soluble with respect to polymers (e.g., piranha solution). Accordingly, such bathing or dousing can cause remnants of the polymer passivation layer to dissolve without harming the floors or sidewalls of the cutface (e.g., without harming the floors or sidewalls of whatever desired high aspect ratio structure is fabricated on or extracted from the cutface). Thus, the cutface (e.g., whatever desired high aspect ratio structure is fabricated on or extracted from the cutface) can now be ready for any suitable follow-on or downstream analysis or fabrication procedure (e.g., transmission electron microscopy analysis or end-pointing).

In various embodiments, the gas injector can utilize various different techniques for delivering the decomposed precursor to the cutface of the specimen. In various aspects, the gas injector can comprise a reservoir, tank, or supply line that contains or houses the reactive gas from which the decomposed precursor is obtained. In various aspects, the gas injector can further comprise a plasma reactor that can receive the reactive gas from the reservoir, tank, or supply line and that can cause (e.g., via application of electromagnetic fields with suitably high frequencies) the reactive gas to breakdown into reactive neutrals and reactive ions (possibly in addition to any other suitable chemical species such as electrons or radicals). In various instances, the gas injector can further comprise a gas nozzle. In situations where the gas injector has an unobstructed line-of-sight to the specimen, the decomposed precursor can be the reactive neutrals that are formed by the plasma reactor, and the gas nozzle can hydraulically spray, stream, or otherwise discharge the reactive neutrals onto the cutface of the specimen. In other situations where the gas injector has no unobstructed line-of-sight to the specimen, the decomposed precursor can instead be the reactive ions that are formed by the plasma reactor, and the gas nozzle can hydraulically spray, stream, or otherwise discharge the reactive ions into the focused ion beam that is emitted by the focused ion beam emitter. In such cases, the focused ion beam can be considered as carrying or copropagating the reactive ions to the cutface of the specimen. In other embodiments, however, the gas injector can lack, omit, or otherwise not utilize the plasma reactor. In such situations, the gas nozzle can spray, stream, or otherwise discharge the reactive gas itself onto the cutface of the specimen, and the focused ion beam can cause the reactive gas to breakdown into the reactive neutrals and the reactive ions. In such cases, the decomposed precursor can be considered as both the reactive neutrals and the reactive ions.

No matter the specific delivery technique implemented by the gas injector, the decomposed precursor can be transported to the cutface, and the focused ion beam can cause the decomposed precursor to polymerize during milling of the cutface. Thus, the polymer passivation layer can be considered as being grown in situ during the milling.

Various embodiments described herein can be employed to use hardware or software to solve problems that are highly technical in nature (e.g., to facilitate in situ protective polymers via milling-excitation), that are not abstract and that cannot be performed as a set of mental acts by a human. Further, some of the processes performed can be performed by a specialized computer (e.g., dual beam microscopes) for carrying out defined acts related to integrated circuit fabrication.

For example, such defined acts can include: milling, by an ion beam emitter, a cutface of a specimen via an ion beam; and delivering, by a gas injector, a decomposed precursor to the cutface, wherein the ion beam can polymerize the decomposed precursor, thereby growing a polymer shield layer on the cutface during the milling. In various aspects, the decomposed precursor can comprise reactive ions or reactive neutrals that are produced via excitation of a reactive gas.

In various instances, the gas injector can have an optical line-of-sight to the cutface, the gas injector can comprise a reservoir for the reactive gas, a plasma reactor, and a gas nozzle, and the defined acts can further comprise: receiving, by the plasma reactor and from the reservoir, the reactive gas; exciting, by the plasma reactor, the reactive gas via an electromagnetic field, thereby breaking the reactive gas into the reactive ions and the reactive neutrals; and discharging, by the gas nozzle, the reactive neutrals to the cutface, wherein the ion beam can polymerize the reactive neutrals, thereby growing the polymer shield layer on the cutface during the milling.

In various cases, the gas injector can have no optical line-of-sight to the cutface, the gas injector can comprise a reservoir for the reactive gas, and the defined acts can further comprise: receiving, by an ion source of the ion beam emitter and from the reservoir, the reactive gas; exciting, by the ion source, the reactive gas via an electromagnetic field, thereby breaking the reactive gas into the reactive ions and the reactive neutrals; and discharging, by the ion source, the ion beam and the reactive ions, wherein the ion beam can carry the reactive ions to the cutface, and wherein the ion beam can polymerize the reactive ions, thereby growing the polymer shield layer on the cutface during the milling.

In various aspects, the gas injector can discharge the reactive gas to the cutface, the ion beam can excite the reactive gas, thereby breaking the reactive gas into the reactive ions and the reactive neutrals, and the ion beam can polymerize the reactive ions and the reactive neutrals, thereby growing the polymer shield layer on the cutface during the milling.

In various instances, the defined acts can include: bathing, by an etcher, the cutface in a dry or wet etchant, thereby removing the polymer shield layer, in response to cessation of the milling.

Such defined acts are inherently computerized and are not mere natural phenomena or laws of nature. Indeed, a scientific instrument, such as a dual beam microscope, is a highly-technical computerized device comprising specific computerized hardware (e.g., temperature sensors, pressure sensors, voltage sensors, ion beam emitters, electron beam emitters, focusing lenses, mass analyzers, electron detectors, beam apertures, fluid valves). A scientific instrument and the operations that it performs are not naturally-occurring and cannot be implemented by the human mind, or by a human with pen and paper, in any reasonable or practicable way without computers. Furthermore, neither nature, the human mind, nor a human with pen and paper can spray, via a gas injector, a decomposed gaseous precursor onto the cutface of a specimen and launch, via a focused ion beam emitter, an ion beam at the cutface so as to mill the specimen while simultaneously causing the decomposed precursor to polymerize on the cutface. In other words, it makes no sense whatsoever to discuss the physical tasks of specimen milling and precursor spraying outside of a computerized hardware context.

Moreover, various embodiments described herein can integrate into a practical application various teachings relating to integrated circuit fabrication. As explained above, it can be desired to form on a specimen, or to otherwise extract from the specimen, a high aspect ratio structure. However, the sidewalls of the high aspect ratio structure can be likely to experience damage during such fabrication or extraction. Some existing techniques attempt to prevent or reduce sidewall damage by placing hard masks or tungsten caps overtop of the specimen. Unfortunately, the hard masks or tungsten caps must be precisely located to avoid unnecessary damage to the specimen and are nevertheless vulnerable to undercutting. Other existing techniques (e.g., the Bosch process) try to prevent sidewall damage by using cyclically-deposited polymer passivation layers whose polymerization reactions are driven by heat or plasma. Unfortunately, such other existing techniques are excessively time-consuming and suffer from scalloping. Thus, existing techniques can be considered as disadvantageous.

Various embodiments described herein can help to ameliorate one or more of these technical problems. In particular, various embodiments described herein can facilitate in situ protective polymers via milling-excitation. More specifically, when given a specimen on which or from which it is desired to fabricate or extract a high aspect ratio structure, various embodiments can involve delivering, spraying, or otherwise discharging a decomposed precursor (e.g., reactive ions or reactive neutrals of an organic fluoride gas) to a cutface of the specimen and bombarding the cutface with a focused ion beam. The focused ion beam can mill the cutface and, at the same time, cause the decomposed precursor to polymerize on the cutface. In other words, the focused ion beam can cause a polymer passivation layer to grow on the floors and sidewalls of the cutface at some rate. Since the focused ion beam can be considered as an anisotropic material removal process, the focused ion beam can mill the floors of the cutface more quickly than it can mill the sidewalls of the cutface. In various aspects, the sputter yield of the focused ion beam with respect to the floors of the cutface can outpace the rate of growth of the polymer passivation layer, whereas the sputter yield of the focused ion beam with respect to the sidewalls of the cutface can fail to outpace the rate of growth of the polymer passivation layer. In other words, the polymer passivation layer cannot grow quickly enough to protect the floors of the cutface from the focused ion beam, but the polymer passivation layer can grow quickly enough to protect the sidewalls of the cutface from the focused ion beam. Thus, the floors of the cutface can be milled or dug to any desired depth while the sidewalls of the cutface can be protected from undercutting, curtaining, erosion, clipping, or other harm by the polymer passivation layer.

Since the polymer passivation layer can be grown during the milling, various embodiments described herein can consume less time than existing techniques (e.g., the Bosch process) which instead require polymer deposition and material removal to be performed sequentially or consecutively. Moreover, since various embodiments described herein can remove material via the anisotropic, physical process of milling, various embodiments described herein can involve no scalloping, unlike existing techniques (e.g., the Bosch process) that instead remove material via the isotropic, chemical process of specimen-selective etching. Furthermore, because the polymer passivation layer can be considered as not difficult to remove (e.g., any suitable polymer-selective etchant can accomplish this), the polymer passivation layer need not be painstakingly positioned on the specimen, unlike hard masks or tungsten caps.

Thus, various embodiments described herein can be considered as addressing or ameliorating various technical problems or disadvantages that plague existing techniques. For at least these reasons, various embodiments described herein can be considered as a concrete and tangible technical improvement in the field of integrated circuit fabrication. Accordingly, various embodiments described herein certainly qualify as useful and practical applications of computers.

Furthermore, it should be appreciated that state-of-the-art teachings in the field of integrated circuit fabrication can be considered as teaching against various embodiments described herein. Indeed, as mentioned above, the Bosch process includes three sequential or consecutive steps that are cycled or repeated multiple times: polymer layer deposition; selective polymer etching; and selective specimen etching. State-of-the-art teachings regarding the Bosch process emphasize the importance of separately performing such three steps. Indeed, the deposition gas utilized in the first step is necessarily different from the etching gases utilized in the second and third steps. Thus, intermediary gas switching or evacuation is performed between those three steps, so as to avoid interfering chemical reactions. In other words, if the deposition gas and the etchants were used at the same time, they would chemically interact with each other in a way that would prevent or severely impede both polymer layer deposition and specimen etching. In still other words, trying to perform the three steps of the Bosch process at the same time as each other would render such three steps inoperable. Accordingly, in view of these state-of-the-art teachings that counsel against simultaneously performing polymer layer deposition and specimen material removal, various embodiments described herein can be considered as highly counter-intuitive. In other words, the herein-described techniques that involve triggering or initiating polymer passivation layer growth via precursor excitation by a milling ion beam can be considered as highly inventive or unexpected (e.g., prior to the work of the present inventors, there was no suggestion or indication that a polymer passivation layer could be grown during or simultaneously as a milling process).

Further still, various embodiments described herein can control real-world tangible devices based on the disclosed teachings. For example, various embodiments described herein can electronically activate, deactivate, or otherwise actuate real-world hardware (e.g., ion beam emitters, ion focusing lenses, carrier fluid valves/pumps) of real-world scientific instruments (e.g., dual beam microscopes) so as to mill or sputter real-world analytical specimens.

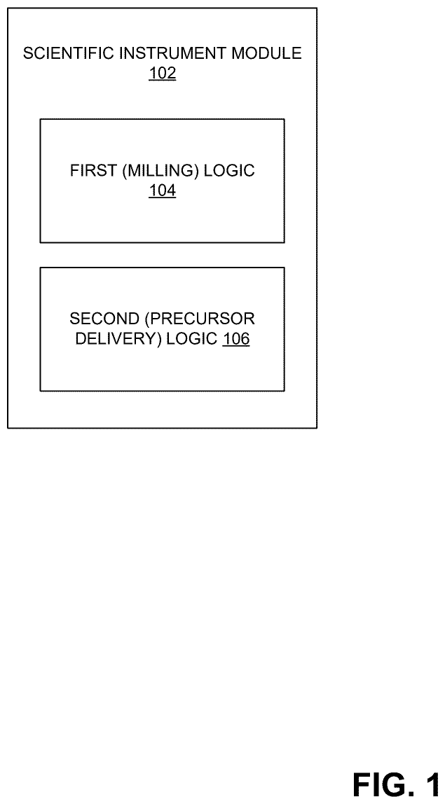

FIG. 1 illustrates an example, non-limiting block diagram of a scientific instrument module 102 in accordance with various embodiments described herein.

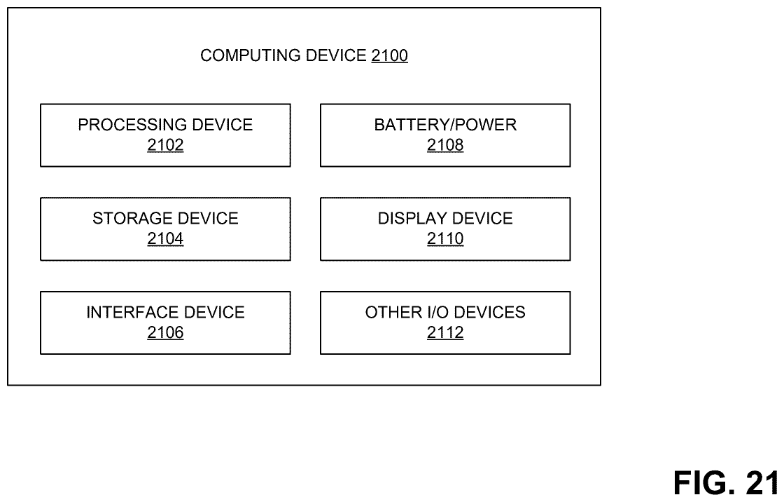

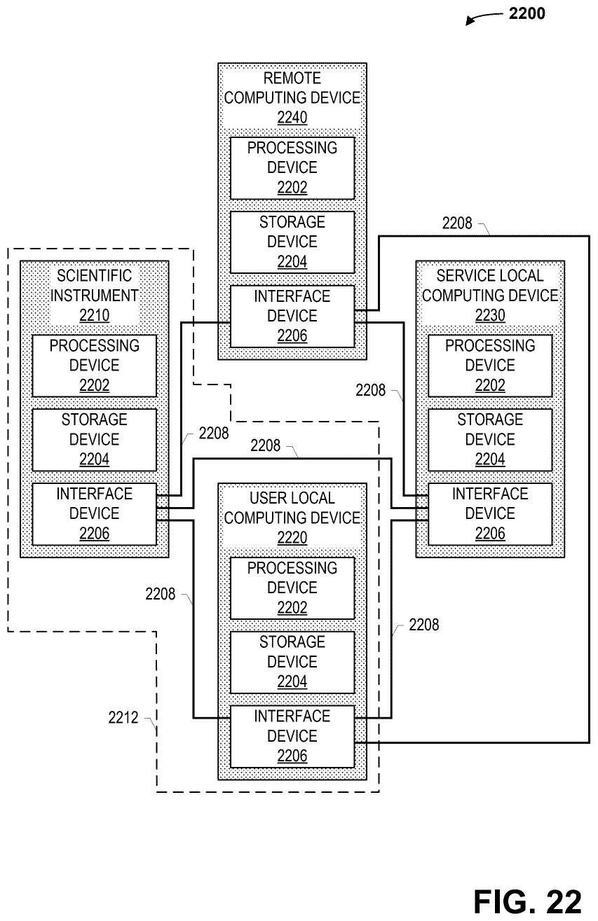

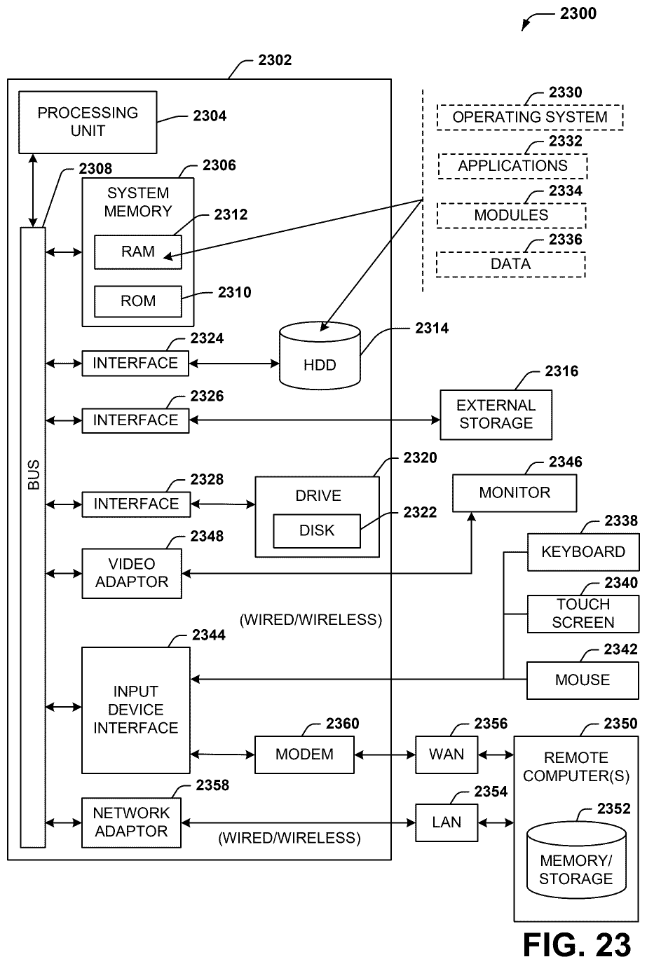

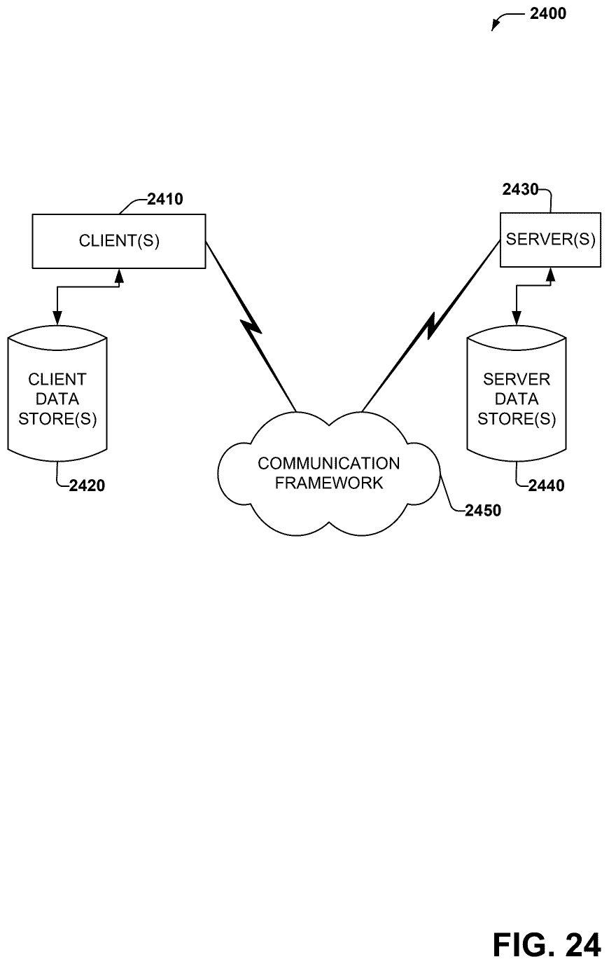

In various embodiments, the scientific instrument module 102 can be implemented by circuitry (e.g., including electrical or optical components), such as a programmed computing device. Logic of the scientific instrument module 102 can be included in a single computing device or can be distributed across multiple computing devices that are in communication with each other as appropriate. Examples of computing devices that may, singly or in combination, implement the scientific instrument module 102 are discussed herein with reference to FIGS. 21 and 23, and examples of systems or networks of interconnected computing devices, in which the scientific instrument module 102 may be implemented across one or more of the computing devices, are discussed herein with reference to FIGS. 22 and 24.

The scientific instrument module 102 can include first logic 104 and second logic 106. As used herein, the term “logic” can include an apparatus that is to perform a set of operations associated with the logic. For example, any of the logic elements included in the scientific instrument module 102 can be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” can refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices. A module can omit one or more of the logic elements depicted in the associated drawings; for example, a module may include a subset of the logic elements depicted in the associated drawings when that module is to perform a subset of the operations discussed herein with reference to that module.

In various embodiments, there can be a scientific instrument corresponding to the scientific instrument module 102. In various aspects, the scientific instrument can be any suitable computerized device that can electronically measure some scientifically-relevant, clinically-relevant, or research-relevant characteristic, property, or attribute of an analytical specimen (e.g., of a known or unknown mixture, compound, or collection of matter). As a non-limiting example, a scientific instrument can be a scanning electron microscope. In such case, the scientific instrument can measure or determine a surface topography of the analytical specimen. As yet another non-limiting example, a scientific instrument can be a transmission electron microscope. In such case, the scientific instrument can measure or determine internal structural details of the analytical specimen. As a more general non-limiting example, a scientific instrument can be any suitable type of charged-particle microscope (e.g., some types of microscopes can use beams of non-electron ions to capture images).

In various aspects, the scientific instrument can be able to perform milling or sputtering on the analytical specimen, so as to fabricate or extract any suitable high aspect ratio structure (e.g., a lamella, a TSV) on or from the analytical specimen. As a non-limiting example, the scientific instrument can be a dual beam microscope that is equipped with both an ion beam emitter and an electron beam emitter. In such case, the ion beam emitter can facilitate milling (e.g., material ejection) of the analytical specimen at various voltage, current, or power levels, and the electron beam emitter can (in conjunction with electron detectors and optical lenses) facilitate imaging of the analytical specimen.

In various instances, the scientific instrument can further be able to expose the analytical specimen to any suitable gases or precursors derived from such gases. As a non-limiting example, the scientific instrument can be a dual beam microscope that is equipped with a gas injector, where the gas injector can pump, flow, or otherwise divert such gases or precursors toward the analytical specimen.

In various embodiments, the first logic 104 can perform, by the ion beam emitter of the scientific instrument, milling on a cutface (e.g., a milling site) of the analytical specimen via an ion beam. In other words, the first logic 104 can instruct or command the ion beam emitter of the scientific instrument to strike or bombard the cutface of the analytical specimen with the ion beam.

In various embodiments, the second logic 106 can deliver, by the gas injector of the scientific instrument, a decomposed precursor to the cutface. In various aspects, the ion beam can polymerize the decomposed precursor, thereby growing a polymer shield layer on the cutface during the milling. More specifically, the decomposed precursor can be physically adjacent or near to the cutface of the analytical specimen, such that the decomposed precursor is exposed to the ion beam that is striking or bombarding the cutface. In various instances, such exposure to the ion beam can excite or otherwise energize the decomposed precursor, and such excitation or energization can cause the decomposed precursor to undergo a polymerization reaction on the cutface. In other words, such excitation or energization can cause the decomposed precursor to form a multitude of polymer chains with itself, such polymer chains can latch onto the various surfaces of the cutface, and such latched polymer chains can collectively be referred to as the polymer shield layer. In various cases, if the gas injector delivers a continuous, continual, or otherwise regular supply of the decomposed precursor to the cutface, the polymer shield layer can continuously, continually, or otherwise regularly grow at some rate on the various surfaces of the cutface. In various aspects, the milling performed by the ion beam emitter of the scientific instrument can sputter away larger amounts of material per unit time on whatever surfaces of the cutface are more perpendicular to a direction or axis of the ion beam, and the milling can instead sputter away smaller amounts of material per unit time on whatever surfaces of the cutface are more parallel to the direction or axis of the ion beam. Accordingly, the ion beam can mill floors of the cutface more quickly than the polymer shield layer is able to grow, and the ion beam can mill sidewalls of the cutface less quickly than the polymer shield layer is able to grow. Thus, the ion beam can dig into the floors of the cutface as deeply as desired, but the ion beam can be unable to dig into the sidewalls of the cutface. Indeed, any material that the ion beam would have removed from the cutface can instead be removed from the polymer shield layer, and the polymer shield layer can be nearly instantaneously replenished or recharged by the polymerization of new or fresh decomposed precursors supplied by the gas injector of the scientific instrument. In this way, high aspect ratio structures can be fabricated or extracted on or from the analytical specimen with no (or otherwise little) sidewall damage.

Accordingly, the scientific instrument module 102 can facilitate in situ protective polymers via milling-excitation.

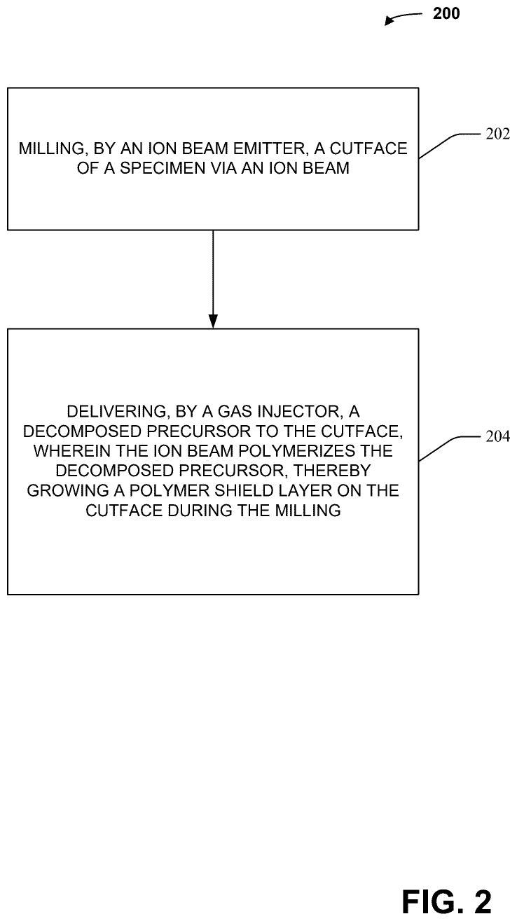

FIG. 2 is an example, non-limiting flow diagram of a method 200 in accordance with various embodiments described herein. The operations of the method 200 may be used in any suitable context to perform any suitable operations (e.g., can be performed by or used in conjunction with any of the various modules, computing devices, or graphical user interfaces described with respect to of FIGS. 1, 20, 21, 22, 23, and 24). Operations are illustrated once each and in a particular order in FIG. 2, but the operations may be reordered or repeated as desired and appropriate (e.g., different operations performed may be performed in parallel, as suitable).

In various aspects, act 202 can include milling, by an ion beam emitter, a cutface of a specimen via an ion beam. In various cases, the first logic 104 can perform or otherwise facilitate act 202.

In various instances, act 204 can include delivering, by a gas injector, a decomposed precursor to the cutface, wherein the ion beam can polymerize the decomposed precursor, thereby growing a polymer shield layer on the cutface during the milling. In various cases, the second logic 106 can perform or otherwise facilitate act 204.

Accordingly, the method 200 can facilitate in situ protective polymers via milling-excitation.

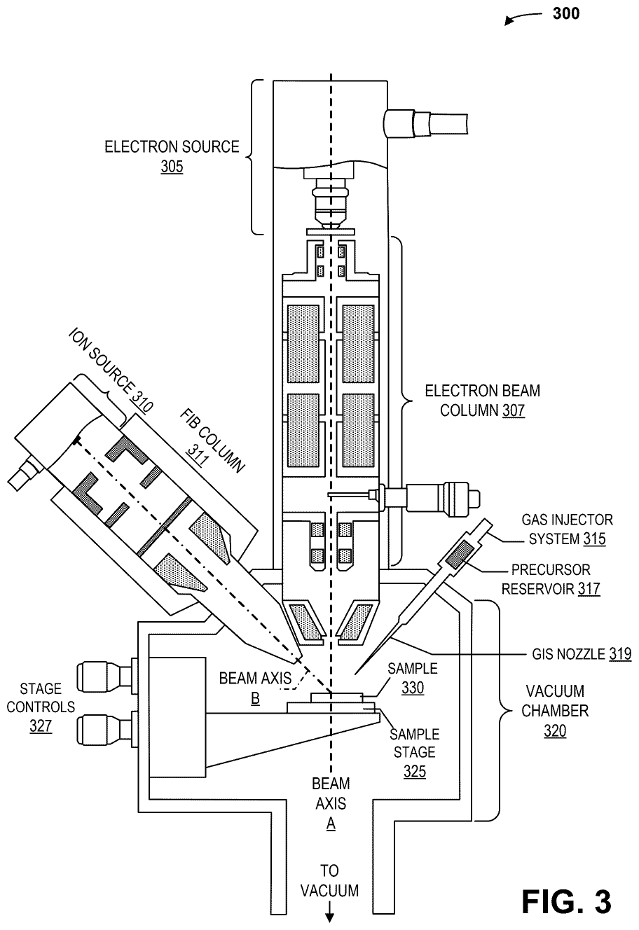

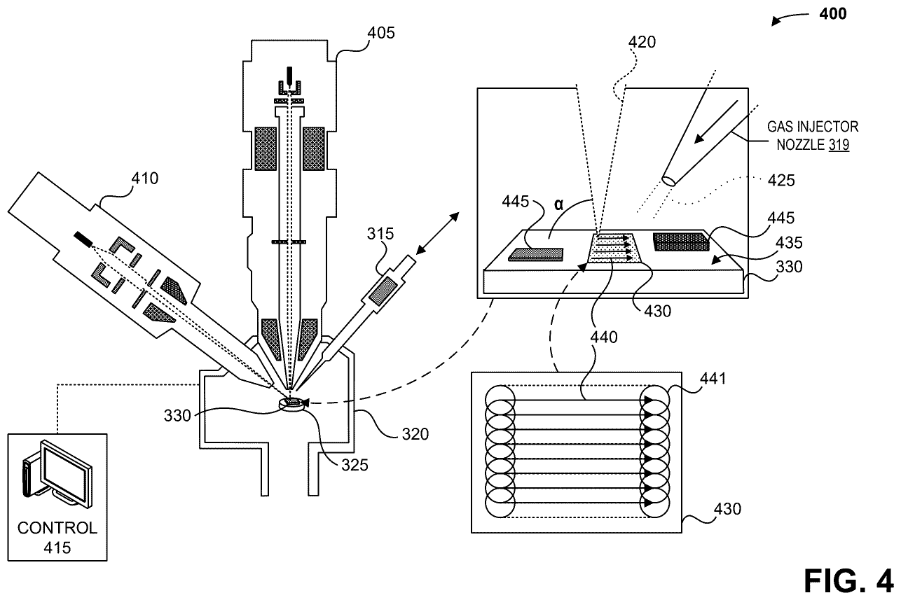

FIGS. 3-4 illustrate example, non-limiting block diagrams of a dual beam microscope in accordance with one or more embodiments described herein.

FIG. 3 is a schematic diagram illustrating an example charged particle beam system 300, in accordance with some embodiments described herein. The example system 300 can include an electron source 305, an electron beam column 307, an ion source 310, a focused ion beam (“FIB”) column 311, a gas injection system (“GIS”) 315, a vacuum chamber 320, or a sample stage 325. The electron beam column 307 is illustrated as a scanning electron microscope (SEM) column, such that the example system 300 corresponds to a dual beam FIB-SEM system. However, this is a mere non-limiting example. In other embodiments, the electron beam column 307 can instead be any other suitable type of electron microscope column (e.g., a transmission electron microscope (TEM) column). The electron beam column 307, the FIB column 311, and the GIS 315 are illustrated as being operably coupled with the vacuum chamber 320, with the electron beam column 307 defining a first beam axis A and the FIB column 311 defining a second beam axis B. The axes A and B are illustrated converging onto a region of a sample 330, with the GIS 315 oriented toward the region of the sample 330 and configured to direct a gas stream including a precursor into the vacuum chamber. Advantageously, while axes A and B can also be oriented toward different locations, convergence permits the SEM system to image the region of the sample 330 that is being processed by the FIB.

The electron source 305 can include one or more emitters configured to generate electrons and to direct the electrons into the electron beam column 307. The emitters can include thermionic emitters, Schottky emitters, field-emission source emitters, or combinations thereof, operably coupled to power systems configured to apply a high-voltage (e.g., on the order of kilovolts to hundreds of kilovolts) to an emission region of the emitter material. For example, the electron source 305 can include a lanthanum hexaboride (LaB6) emitter crystal to which a high electrical potential is applied to elicit the emission of electrons from a tip of the emitter crystal. In this way, a beam of electrons can be directed into the electron beam column 307. The electron beam column 307 can include electromagnetic optics (e.g., electrostatic lenses, electromagnetic lenses, monochromators) and apertures configured to shape, focus, defocus, or otherwise direct the beam of electrons such that the beam can be focused onto the sample 330, in accordance with a set of operating parameters. The operating parameters can include a beam current, a beam energy (e.g., in volts, in electron volts, or the like), a magnification parameter, a scan pattern, a dwell time, or one or more pulse parameters. In this way, the example system 300 can function as an SEM to image portions of the sample 330 or can be used for e-beam assisted deposition of material (e.g., protective polymer growth, as described herein) onto the sample 330 (e.g., in coordination with the GIS 315).

In a non-limiting example, the beam energy can be from about 1 keV to about 50 keV, including subranges, fractions, or interpolations thereof. Beam energies below about 1 keV can correspond with reduced pattern fidelity, while beam energies above about 50 keV can reduce the secondary electron yield below a level at which deposition can be impaired significantly or negligible. To that end, precursor decomposition and deposition reactions can be mediated by secondary electrons emitted from the sample 330, which can be characterized by lower energies than the primary electrons of the beam (e.g., at about 50 eV or less). In this way, the beam energy can be selected at least in part based on the secondary electron emission function of the material of the sample 330, which can depend at least in part on the beam energy, for imaging purposes, to reduce damage to the sample 330, or to promote deposition (e.g., to promote polymer growth).

The ion source 310 can include one or more components configured to generate a beam of ions and to direct the ions into the FIB column 311. The ions can include metal ions or nonmetal ions (e.g., noble gas, halogen, oxygen, nitrogen, or the like). To that end, the ion source 310 can include a plasma source (e.g., an inductively coupled plasma source) or a metal ion source (e.g., a liquid-metal ion source). As with the electron beam column 307, the FIB column 311 can include electromagnetic optics (e.g., electrostatic lenses, electromagnetic lenses, monochromators) or apertures configured to shape, focus, defocus, or otherwise direct the beam of ions such that the beam can be focused onto the sample 330, in accordance with a set of operating parameters. The operating parameters can include a beam current, a beam energy (e.g., in volts, in electron volts, or the like), a magnification parameter, a scan pattern, a dwell time, or one or more pulse parameters. In this way, the example system 300 can function as an FIB to remove, sputter, or mill portions of the sample 330 or can be used for ion-beam assisted deposition of material (e.g., protective polymer growth, as described herein) onto the sample 330 (e.g., in coordination with the GIS 315). Analogous to the energies described in reference to the electron beam, above, the ion beam energy can be selected (e.g., by a user, by an algorithm initiated by a user, or automatically without user intervention) such that the beam delivers enough energy for beam-induced deposition to occur (e.g., for protective polymer growth to occur), but not such that the beam degrades the sample 330 or degrades the precursor without forming deposited material layers on the sample 330. In some embodiments, additional or alternative precursor decomposition mechanisms (e.g., surface activation or secondary electron reemission) can be used as a mechanism for precursor decomposition, thereby allowing the ion beam energy to be determined based at least in part on a relationship between beam energy, sample material properties, and the energetic characteristics of the precursor deposition reaction mechanism. Advantageously, ion beam-induced deposition (e.g., protective polymer growth via milling-excitation) can elicit relatively high yields, in comparison to electron beam-induced deposition (e.g., protective polymer growth via electron-beam excitation), based at least in part on the combined effect of multiple energy transfer pathways.

The GIS 315 can include constituent elements that together permit the GIS 315 to generate a gas stream including the precursor and to direct the gas stream into the vacuum chamber. The components of the GIS 315 can include a carrier gas inlet, a nozzle 319, or a conduit fluidically coupling the nozzle 319 and a precursor reservoir 317. The precursor reservoir 317 can include a substantially non-reactive container (e.g., a ceramic crucible, a polytetrafluoroethylene (PTFE) enclosure, a non-reactive metal or alloy, or the like) that is at least partially exposed to the conduit. In this way, vapor generated from a precursor disposed in the precursor reservoir 317 can be directed toward the nozzle 319 and into the vacuum chamber 320 (e.g., by pressure-driven flow induced by a pressure gradient relative to the vacuum of the vacuum chamber 320). In some embodiments, the GIS 315 can include a carrier gas inlet, fluidically coupled with the nozzle 319 via the conduit. In this way, the precursor can be entrained in a flow of carrier gas and directed toward the nozzle 319 and into the vacuum chamber 320. Additionally or alternatively, the precursor can include a gas at standard conditions and can be introduced to the GIS 315 via a gas inlet provided as part of the GIS 315.

In a non-limiting example, the precursor can be or include a material that is a solid at standard temperature and pressure and at least partially sublimates to form a vapor at reduced pressure and a temperature above about 273 K. To that end, the GIS 315 can include a heating circuit that is thermally coupled with the precursor reservoir 317 and configured to heat the precursor to within a range of temperatures that elicits at least partial vaporization into the carrier gas flow. In some embodiments, the temperature can be from about 273 K to about 385 K, including sub-ranges, fractions, or interpolations thereof. The temperature can be selected based at least in part on a vapor pressure estimate for the precursor, as part of controlling the composition of the gas stream entering the vacuum chamber 320. Such estimates can be determined using empirically derived heuristics for a given charged particle beam system or can be derived using thermodynamic first principles. In some cases, the temperature and carrier gas flowrate can be selected based at least in part on an operational window determined from experimental calibration of a given charged particle beam system (e.g., for a given sample material and precursor material).

The operation of one or more components of the example system 300 can be coordinated by control circuitry (e.g., electronic control circuitry 415 of FIG. 4), in accordance with machine-executable instructions (e.g., software, firmware, etc.) that can be stored in machine-readable storage media or received from external systems via wired or wireless communication techniques (e.g., over a WiFi or Bluetooth link). To that end, components of the example system 300 can be automated (e.g., operating without human intervention), pseudo-automated (e.g., operating with limited human intervention to initiate operations, analyze output and confirm, or the like), or manually operated (e.g., where individual operations of the example system 300 are performed by a human user). In an illustrative example, the sample stage 325 can be mechanically coupled with automated stage controls 327 that permit the sample 330 to be reversibly tilted relative to the beam axes A and B, such that the surface of the sample 330 is substantially normal to a given beam axis during operation of the corresponding charged particle beam source. In this way, the operation of a given beam source can be coordinated with the operation of the stage controls 327. Similarly, the operation of the GIS 315 can be coordinated with the operation of the stage controls 327 and a given beam source (e.g., the electron source 305 or the ion source 310).

Various embodiments can omit one or more components of the example system 300. For example, one or more of the electron source 305, of the ion source 310, of the electron beam column 307, or of the FIB column 311 can be omitted. In a non-limiting example, an SEM system can be configured to perform operations of the beam-induced deposition processes (e.g., of the protective polymer growth processes) described herein. Similarly, an FIB system other than a dual-beam FIB-SEM (e.g., a FIB system for which two or more beam axes are not convergently trained on a given region of the sample 330) can include the GIS 315 oriented to be convergent with the second beam axis B.

FIG. 4 is a schematic diagram illustrating an example charged particle beam system 400 performing operations of a process for beam-induced deposition (e.g., for in situ protective polymer growth via milling-excitation), in accordance with some embodiments described herein. The example system 400 can include or omit some of the components of the example system 300 described in reference to FIG. 3. To that end, the example system 400 can include an SEM 405 (e.g., including electron source 305 and electron beam column 307), an FIB 410 (e.g., including ion source 310 and FIB column 311), the GIS 315, the vacuum chamber 320, or the sample stage 325 to which the sample 330 can be mechanically coupled. The example system 400 can include electronic control circuitry 415, by whose operation at least a portion of a beam-induced deposition process (e.g., of in situ protective polymer growth via milling-excitation) can be coordinated.

The operations of the process for beam-induced deposition (e.g., for in situ protective polymer growth via milling-excitation) can include positioning the sample 330 in the vacuum chamber 320 such that the SEM 405, the FIB 410, or the GIS 315 are configured to direct a beam of charged particles 420 or a gas stream 425, respectively, toward a region of interest (ROI) 430 on a surface 435 of the sample 330. In cases where the beam of charged particles 420 and the gas stream 425 are substantially convergent, the ROI 430 can include a locus in the vacuum chamber 320. In this context, the locus can be defined at least in part by an intersection of the beam axes A and B, the gas stream 425, and the position of the sample stage 325 in the vacuum chamber 320. In some embodiments, the GIS 315 can be repositioned relative to the locus such that the nozzle 319 can be moved relative to the sample 330, and the average concentration of precursor at the surface 435 of the sample 330 can be controlled independently of the composition of the gas stream 425 itself (e.g., as determined by the operating parameters of the GIS 315).

An offset between the surface 435 of the sample 330 and the sample stage 325 can be estimated or measured using various techniques including focal-distance estimation in imaging mode using the SEM 405 or range-finding or profilometry techniques. The deposition process (e.g., the protective polymer growth process), therefore, can include positioning the sample stage 325 in the vacuum chamber 320 such that the surface 435 of the sample 330 more generally, and the ROI 430 more specifically, coincides at least partially with the locus. Positioning the sample stage 325 can include tilting the sample stage 325, as described in more detail in reference to FIG. 3, such that the beam of charged particles 420 can be oriented relative to the surface 435 of the sample 330 at an angle, “α.” The angle α can be from about 0 radians (rad) to about π rad, or about 0 degrees to about 180 degrees, where a value of about π/2 rad or 90 degrees corresponds to substantially normal incidence of the beam of charged particles 420 with the surface 435 of the sample 330. In some cases, the value of the angle α can be selected based at least in part on topography of the surface 435 of the sample 330. For example, where the sample 330 includes surface features such as sidewalls or other features oriented at a nonzero angle relative to the surface 435 of the sample 330, the sample stage 325 can be oriented such that the angle α corresponds to substantially normal incidence of the beam of charged particles 420 and the local surface of the feature.

In some embodiments, the angle α can be dynamic during a deposition (e.g., polymer growth) process. Advantageously, tilting the sample stage 325 during a deposition (e.g., polymer growth) process can be used to form substantially conformal coatings in the ROI 430 that includes topography that would otherwise produce shadows. In some embodiments, portions of the sample 330 can be used to generate secondary electrons, rather than directly irradiating the surface of the ROI 430. In this way, coating hidden surfaces (e.g., out of line of sight of the beam of charged particles 420) can be facilitated by directing the beam of charged particles 420 to positions around or within the ROI 430. To that end, for SEM 405 or FIB 410, the beam of charged particles 420 can be scanned across the surface 435 of the sample 330, within or outside the ROI 430, in accordance with a scan pattern 440. The scan pattern 440 can include a linear translation across the surface 435 of the sample 330, but can also include more complex patterns, such as raster patterns, geometric patterns, or discontinuous patterns.

The beam of charged particles 420 can irradiate a portion of the surface 435 of the sample 330 described by a spot size 441. To that end, the scan pattern 440 can be defined (e.g., as a time-dependent voltage signal or signals generated to control scan coils of the SEM 405) such that the beam spot overlaps at least partially as it rasters or otherwise transits across the surface 435 of the sample 330. The average energy provided to the surface 435 and localized secondary electron remission can be manipulated using an overlap percentage of the scan pattern 440 that can be determined based at least in part on geometric aspects of the spot size 441 and the scan pattern 440. Advantageously, this can provide a variety of control parameters to improve the quality of deposited material layers 445 (e.g., of the polymer passivation layers that are grown during milling).

In various aspects, the dimensions, composition, spatial characteristics, surface properties, chemical properties, or physical properties of the deposited material layers 445 can be influenced by selecting a set of operating parameters for the example system 400. For example, the composition of the gas stream 425, the distance of the nozzle 319 from the surface 435 of the sample 330, and the volumetric flowrate of the gas stream 425 can independently affect the concentration of precursor near the surface 435 of the sample 330 or the equilibrium surface coverage, θ, of precursor on the surface 435. As the equilibrium surface coverage θ also depends on environmental factors including the local temperature of the surface in the ROI 430, the pressure in the vacuum chamber 320, and the composition of the sample 330, beam-induced deposition (e.g., in situ protective polymer growth via milling-excitation) can be modulated by multiple variables that do not involve SEM 405 or FIB 410 operating parameters. With respect to the SEM 405 or FIB 410 parameters, beam current, beam energy, spot size 441, dwell time, overlap percentage, or other aspects of the scan pattern 440 can be modulated to influence some or all of the material properties of the layers 445.

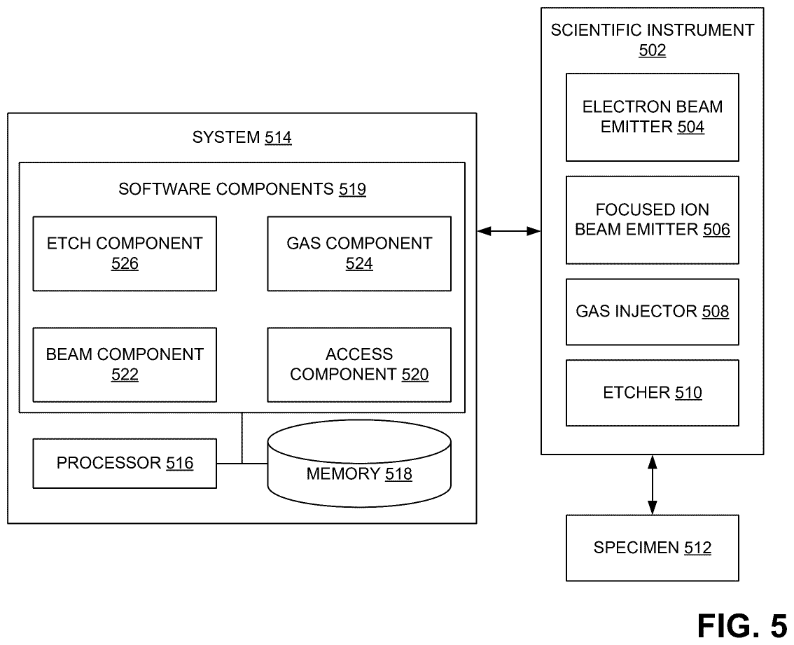

FIG. 5 illustrates a block diagram of an example, non-limiting system that can facilitate in situ protective polymers via milling-excitation in accordance with one or more embodiments described herein.

In various embodiments, there can be a scientific instrument 502. In various aspects, the scientific instrument 502 can be any suitable scientific instrument as described above. As a non-limiting example, the scientific instrument 502 can be a dual beam microscope, such as described with respect to FIGS. 3-4. Accordingly, the scientific instrument 502 can comprise an electron beam emitter 504 (hereafter “e-beam emitter 504”), a focused ion beam emitter 506 (hereafter “FIB emitter 506”), and a gas injector 508.

In various aspects, the e-beam emitter 504 can comprise or otherwise be any suitable mechanism or machinery that can controllably utilize an emitted electron beam so as to facilitate imaging or image-capture of any suitable specimens. For example, the e-beam emitter 504 can comprise any suitable electron source (e.g., 305), can comprise any suitable electron beam column (e.g., 307), can comprise any suitable optical elements (e.g., focusing lens, deflection plates, apertures, detectors), or can otherwise be like the SEM 405 described above.

In various instances, the FIB emitter 506 can comprise or otherwise be any suitable mechanism or machinery that can controllably utilize an emitted ion beam so as to facilitate milling or sputtering of any suitable specimens. As some non-limiting examples, the FIB emitter 506 can comprise any suitable ion source (e.g., 310), can comprise any suitable FIB column (e.g., 311), can comprise any suitable optical elements (e.g., focusing lens, deflection plates, apertures), or can otherwise be like the FIB 410 described above.

In various cases, the gas injector 508 can comprise or otherwise be any suitable mechanism or machinery that can controllably pump, spray, or otherwise divert any suitable gaseous precursors to or toward any suitable specimens. As some non-limiting examples, the gas injector 508 can comprise any suitable nozzle (e.g., 319), can comprise any suitable precursor reservoir (e.g., 317), can comprise any suitable fluidic or hydraulic elements (e.g., actuatable pumps, actuatable valves, actuatable syringes, piping or conduits) for transporting gases or gaseous precursors, or can otherwise be like the GIS 315 described above.

In various aspects, as shown, the scientific instrument 502 can further comprise an etcher 510. In various instances, the etcher 510 can comprise or otherwise be any suitable mechanism or machinery that can controllably pump, spray, or otherwise divert any suitable dry or wet etchant to or toward any suitable specimens. As some non-limiting examples, the etcher 510 can comprise any suitable nozzle, any suitable etchant reservoir or supply line, or any suitable fluidic or hydraulic elements (e.g., actuatable pumps, actuatable valves, actuatable syringes, piping or conduits) for transporting dry or wet etchants.

In various aspects, there can be a specimen 512. In various instances, the specimen 512 can be any suitable sample (e.g., 330) or portion thereof having or otherwise exhibiting any suitable chemical or physical composition or construction. As a non-limiting example, the specimen 512 can be any suitable semiconductor substrate or wafer (e.g., a silicon substrate or wafer) on which any suitable microelectromechanical circuitry components or integrated circuitry components are fabricated or otherwise manufactured. For instance, such circuitry components can include: field effect transistor fins; field effect transistor gates; field effect transistor source drains; diode anodes; diode cathodes; resistor dielectrics; resistor insulators; planar capacitor pads; Josephson junctions; or waveguides. As another non-limiting example, the specimen 512 can instead be any suitable semiconductor substrate or wafer that is bare (e.g., on which microelectromechanical circuitry components or integrated circuitry components are not yet fabricated or manufactured).

In any case, the specimen 512 can be placed on any suitable actuatable stage (e.g., 325) of the scientific instrument 502 (e.g., such stage can be within a vacuum chamber of the scientific instrument 502), and it can be desired to utilize the scientific instrument 502 so as to fabricate any suitable high aspect ratio structure on the specimen 512, or so as to extract, cut, or separate any suitable high aspect ratio structure from the specimen 512. As a non-limiting example, it can be desired to extract or cut a lamella from the specimen 512, which can be any suitable rectangular plate, layer, or slice of the specimen 512. In various cases, a thickness of the lamella can be one or more orders of magnitude smaller than its length and width (e.g., the thickness of the lamella can range from 50 nm to 130 nm, whereas the length and width of the lamella can instead each measure on the order of micrometers). As another non-limiting example, it can be desired to fabricate or manufacture a TSV on the specimen 512, which can be a tunnel or hole filled with a conductive material (e.g., copper) that electrically couples one side, level, or plane of the specimen 512 to some other side, level, or plane of the specimen 512. In various cases, cross-sectional dimensions (e.g., diameter) of the TSV can be one or more orders of magnitude smaller than its length or height (e.g., some TSVs can measure on the order of hundreds of micrometers in length or height and merely a dozen micrometers in diameter or width).

In various aspects, a system 514 can be electronically integrated (e.g., via any suitable wired or wireless electronic connections) with the scientific instrument 502. In various instances, the system 514 can be implemented in or otherwise as part of the electronic control circuitry 415. In various cases, as described herein, the system 514 can help to facilitate fabrication or extraction of the desired high aspect ratio structure on or from the specimen 512.

In various aspects, the system 514 can comprise a processor 516 (e.g., computer processing unit, microprocessor) and a non-transitory computer-readable memory 518 that is operably or operatively or communicatively connected or coupled to the processor 516. The non-transitory computer-readable memory 518 can store computer-executable instructions which, upon execution by the processor 516, can cause the processor 516 or other components of the system 514 (e.g., access component 520, beam component 522, gas component 524, etch component 526) to perform one or more acts. In various embodiments, the non-transitory computer-readable memory 518 can store computer-executable components (e.g., access component 520, beam component 522, gas component 524, etch component 526), and the processor 516 can execute the computer-executable components.

In various embodiments, the system 514 can comprise an access component 520. In various aspects, the access component 520 can electronically access the scientific instrument 502. That is, the access component 520 can electronically communicate or otherwise electronically interact with (e.g., transmit electronic instructions or commands to, receive electronic data from) the scientific instrument 502. Accordingly, the access component 520 can be considered as a proxy or conduit through which other components of the system 514 can interact with, communicate with, or otherwise manipulate the scientific instrument 502. However, this is a mere non-limiting example. In other cases, the access component 520 can be omitted, and any other components of the system 514 can communicate or interact directly with the scientific instrument 502.

In various embodiments, the system 514 can comprise a beam component 522. In various aspects, the beam component 522 can electronically control, electronically manage, electronically govern, or otherwise electronically influence the FIB emitter 506. As a non-limiting example, the beam component 522 can electronically transmit (e.g., via or through the access component 520) an activation instruction to the FIB emitter 506, where the activation instruction can command or otherwise cause the FIB emitter 506 to begin or start bombarding the cutface of the specimen 512 with a focused ion beam. As another non-limiting example, the beam component 522 can electronically transmit a deactivation instruction to the FIB emitter 506, where the deactivation instruction can command or otherwise cause the FIB emitter 506 to stop or cease bombarding the cutface of the specimen 512 with a focused ion beam. As yet another non-limiting example, the beam component 522 can electronically transmit a parameter instruction to the FIB emitter 506, where the parameter instruction can cause the FIB emitter 506 to alter or otherwise change any suitable configurable operating parameters or settings associated with the FIB emitter 506 or with a focused ion beam produced by the FIB emitter 506. For instance, some of such configurable operating parameters or settings can include: a voltage level of the FIB emitter 506; an electric current level of the FIB emitter 506; a focal spot size of a focused ion beam emitted by the FIB emitter 506; a dwell time of a focused ion beam emitted by the FIB emitter 506; or a point of aim of a focused ion beam emitted by the FIB emitter 506 (e.g., changing where on the cutface of the specimen 512 the focused ion beam is aiming, striking, or bombarding). It should be appreciated that altering or changing a point of aim of a focused ion beam can, in some cases, involve altering or changing a position or orientation of an actuatable stage (e.g., 325) of the scientific instrument 502.

In various aspects, the beam component 522 can also electronically control, electronically manage, electronically govern, or otherwise electronically influence the e-beam emitter 504. As a non-limiting example, the beam component 522 can electronically transmit (e.g., via or through the access component 520) an activation instruction to the e-beam emitter 504, where the activation instruction can command or otherwise cause the e-beam emitter 504 to begin or start bombarding the cutface of the specimen 512 with an electron beam. As another non-limiting example, the beam component 522 can electronically transmit a deactivation instruction to the e-beam emitter 504, where the deactivation instruction can command or otherwise cause the e-beam emitter 504 to stop or cease bombarding the cutface of the specimen 512 with an electron beam. As yet another non-limiting example, the beam component 522 can electronically transmit a parameter instruction to the e-beam emitter 504, where the parameter instruction can cause the e-beam emitter 504 to alter or otherwise change any suitable configurable operating parameters or settings associated with the e-beam emitter 504 or with an electron beam produced by the e-beam emitter 504. For instance, some of such configurable operating parameters or settings can include: a voltage level of the e-beam emitter 504; an electric current level of the e-beam emitter 504; a focal spot size of an electron beam emitted by the e-beam emitter 504; a dwell time of an electron beam emitted by the e-beam emitter 504; or a point of aim of an electron beam emitted by the e-beam emitter 504 (e.g., changing where on the cutface of the specimen 512 the electron beam is aiming, striking, or bombarding). Again, it should be appreciated that altering or changing a point of aim of an electron beam can, in some cases, involve altering or changing a position or orientation of an actuatable stage (e.g., 325) of the scientific instrument 502.

In various embodiments, the system 514 can comprise a gas component 524. In various aspects, the gas component 524 can electronically control, electronically manage, electronically govern, or otherwise electronically influence the gas injector 508. As a non-limiting example, the gas component 524 can electronically transmit (e.g., via or through the access component 520) an activation instruction to the gas injector 508, where the activation instruction can command or otherwise cause the gas injector 508 to begin or start delivering a decomposed precursor of a reactive gas to the cutface of the specimen 512. As another non-limiting example, the gas component 524 can electronically transmit a deactivation instruction to the gas injector 508, where the deactivation instruction can command or otherwise cause the gas injector 508 to stop or cease delivering the decomposed precursor to the cutface of the specimen 512. As yet another non-limiting example, the gas component 524 can electronically transmit a parameter instruction to the gas injector 508, where the parameter instruction can cause the gas injector 508 to alter or otherwise change any suitable configurable operating parameters or settings associated with the gas injector 508 or with the decomposed precursor sprayed by the gas injector 508. For instance, some of such configurable operating parameters or settings can include: a voltage level of the gas injector 508; an electric current level of the gas injector 508; a fluid flowrate of the decomposed precursor; a concentration of the decomposed precursor; or a point of aim of a nozzle of the gas injector 508 (e.g., changing where on the cutface of the specimen 512 the gas injector 508 delivers the decomposed precursor). As above, it should be appreciated that altering or changing a point of aim of a nozzle of the gas injector 508 can, in some cases, involve altering or changing a position or orientation of an actuatable stage (e.g., 325) of the scientific instrument 502.

In various embodiments, the system 514 can comprise an etch component 526. In various aspects, the etch component 526 can electronically control, electronically manage, electronically govern, or otherwise electronically influence the etcher 510. As a non-limiting example, the etch component 526 can electronically transmit (e.g., via or through the access component 520) an activation instruction to the etcher 510, where the activation instruction can command or otherwise cause the etcher 510 to begin or start bathing or dousing the cutface of the specimen 512 in an etchant. As another non-limiting example, the etch component 526 can electronically transmit a deactivation instruction to the etcher 510, where the deactivation instruction can command or otherwise cause the etcher 510 to stop or cease bathing or dousing the cutface of the specimen 512 in an etchant. As yet another non-limiting example, the etch component 526 can electronically transmit a parameter instruction to the etcher 510, where the parameter instruction can cause the etcher 510 to alter or otherwise change any suitable configurable operating parameters or settings associated with the etcher 510 or with the etchant that is sprayed by the etcher 510. For instance, some of such configurable operating parameters or settings can include: a voltage level of the etcher 510; an electric current level of the etcher 510; a fluid flowrate of the etchant; a concentration of the etchant; a pH of the etchant; or a point of aim of a nozzle of the etcher 510 (e.g., changing where on the cutface of the specimen 512 the etcher 510 delivers the etchant). Once more, it should be appreciated that altering or changing a point of aim of a nozzle of the etcher 510 can, in some cases, involve altering or changing a position or orientation of an actuatable stage (e.g., 325) of the scientific instrument 502.

Note that, in various instances, the access component 520, the beam component 522, the gas component 524, and the etch component 526 can collectively be considered as being one or more software components 519 of the system 514. In various aspects, it should be appreciated that the one or more software components 519 are described primarily herein as comprising four components (e.g., the access component 520, the beam component 522, the gas component 524, and the etch component 526) for ease of explanation and illustration. However, the one or more software components 519 are not limited to being implemented as exactly such four components in every embodiment. Indeed, in some embodiments, the functionalities described herein of such four components can be combined in any suitable fashions, so as to be implemented in or by fewer than four components (e.g., in some cases, a single component can perform all of the functionalities that are described herein with respect to the access component 520, the beam component 522, the gas component 524, and the etch component 526). In other embodiments, the functionalities described herein of such four components can instead be distributed, separated, split, or fragmented in any suitable fashions, so as to be implemented in or by more than four components (e.g., two or more components can facilitate the functionalities that are performable by the access component 520; two or more components can facilitate the functionalities that are performable by the beam component 522; two or more components can facilitate the functionalities that are performable by the gas component 524; two or more components can facilitate the functionalities that are performable by the etch component 526).

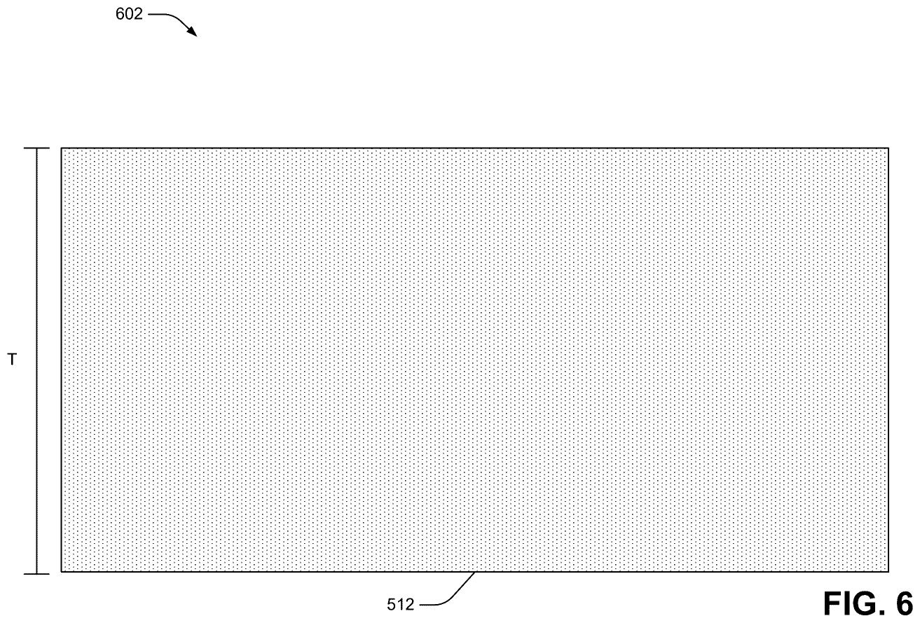

Now, in various embodiments, the gas component 524 can electronically instruct or cause the gas injector 508 to continuously, continually, or otherwise regularly deliver or otherwise transport a decomposed precursor (e.g., a reactive ion or a reactive neutral) of a reactive gas (e.g., an organic fluoride) to the cutface of the specimen 512. In various aspects, the beam component 522 can electronically instruct or cause the FIB emitter 506 to strike or bombard the cutface of the specimen 512 with an ion beam. In various instances, the ion beam can cause the decomposed precursor to polymerize on the cutface of the specimen 512, so as to grow a polymer shield layer on whatever surfaces make up the cutface of the specimen 512. In various cases, simultaneously with the growth of the polymer shield layer, the ion beam can mill or sputter atoms away from whatever surfaces make up the cutface of the specimen 512. The ion beam can be anisotropic, such that the ion beam mills or sputters more atoms away from surfaces that are more orthogonal to its beam axis, and such that the ion beam mills or sputters fewer atoms away from surfaces that are more parallel to its beam axis. Accordingly, the ion beam can mill or sputter atoms away from floors of the cutface more quickly than the polymer shield layer can grow, and the ion beam can mill or sputter atoms away from sidewalls of the cutface less quickly than the polymer shield layer can grow. Thus, the polymer shield layer can ultimately be unable to protect floors of the cutface from being milled or dug into by the ion beam, but the polymer shield layer can protect sidewalls of the cutface from being milled or dug into by the ion beam. In this way, structures or trenches having high aspect ratios (e.g., aspect ratios of 50 or greater) can be formed in or extracted from the cutface of the specimen 512, without much (if any) harm befalling sidewalls of such structures or trenches. Once such structures or trenches have been milled or dug to a desired depth or aspect ratio, the beam component 522 can electronically instruct or cause the FIB emitter 506 to cease striking or bombarding the cutface with the ion beam, and the gas component 524 can likewise instruct or command the gas injector 508 to cease delivering the decomposed precursor to the cutface. In various cases, the etch component 526 can then electronically instruct or cause the etcher 510 to bathe or douse the cutface in any suitable etchant (e.g., piranha solution), so as to remove any remnants of the polymer shield layer from the cutface. At such point, the structure or trench that is formed on or extracted from the cutface of the specimen 512 can be considered as being ready for any suitable next, following, or downstream fabrication process or analysis (e.g., TEM analysis). Various non-limiting aspects are described with respect to FIGS. 6-13.

FIGS. 6-13 illustrate example, non-limiting block diagrams showing how a polymer shield layer can be grown during milling in accordance with one or more embodiments described herein.

First, consider FIG. 6. FIG. 6 depicts a profile-view of an example, non-limiting embodiment of the specimen 512. In the non-limiting example of FIG. 6, the specimen 512 is depicted as a semiconductor substrate or wafer of thickness t micrometers, for any suitable positive real number t. Note that, for ease of illustration and explanation, the portion of the specimen 512 that is depicted in FIG. 6 is shown as bare. In other words, FIG. 6 does not depict any other structures (e.g., integrated circuit components, such as resistors, capacitors, transistors, bump bonds, waveguides, or Josephson junctions) as being fabricated or manufactured (e.g., via photolithography) on or in the specimen 512. Nevertheless, it should be appreciated that any suitable portions of the specimen 512 can already contain any of such structures.

In any case, it can be desired to fabricate on, or to otherwise extract from, a cutface 602 of the specimen 512 any suitable high aspect ratio structure, such as a lamella or a TSV. In various instances, such fabrication or extraction can be accomplished by milling or digging any suitable patterns, shapes, or trenches to any suitable depths into the cutface 602. In some cases, this can be considered as a form of subtractive manufacturing.

Note that the scientific instrument 502 can localize the cutface 602 (e.g., can find where the cutface 602 is located or positioned on the specimen 512), by capturing one or more images of the specimen 512 via the e-beam emitter 504. After the cutface 602 is localized, the FIB emitter 506, the gas injector 508, or the etcher 510 can be aimed at or otherwise toward the cutface 602.

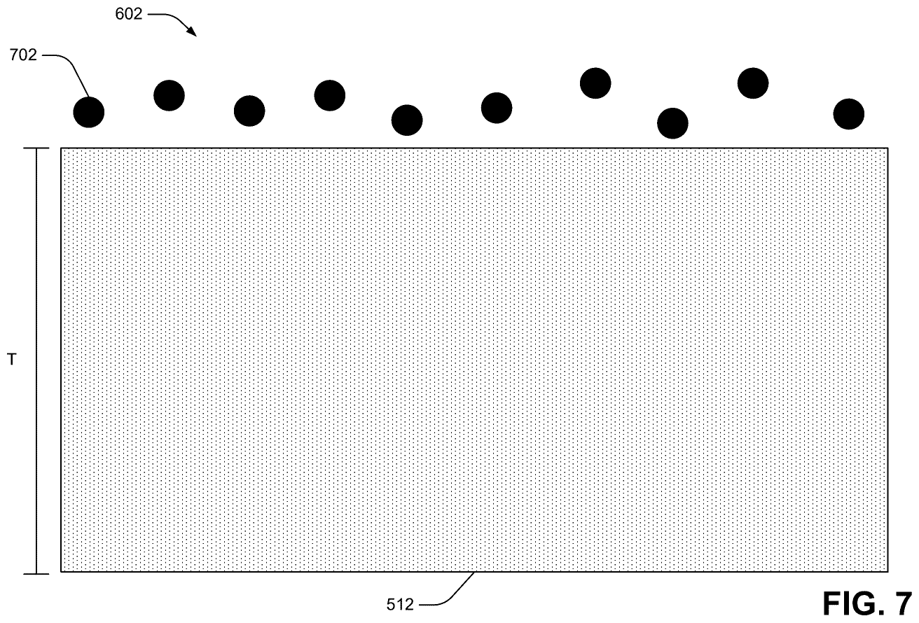

Now, consider FIG. 7. In various aspects, the gas component 524 can electronically instruct, command, or otherwise cause the gas injector 508 to continuously, continually, periodically, or otherwise regularly deliver or transport a decomposed precursor 702 to the cutface 602. In various instances, the decomposed precursor 702 can be any suitable reactive ion or any suitable reactive neutral, either of which can be formed by decomposition or excitation of any suitable reactive gas. In various cases, the reactive gas can be any suitable organic fluoride gas. As some non-limiting examples, the reactive gas can be: any suitable fluorocarbon gas; any suitable hydrofluorether gas; any suitable perfluorocarbon gas; any suitable clorofluorcarbon gas; any suitable hydroclorofluorocarbon gas; any suitable hydrofluorocarbon gas; or any suitable fluorether gas. As even more specific non-limiting examples, the reactive gas can be any of the following: C₇F₁₆; C₇F₁₄; CoF₆; C₄F₈; CF₄; CHF₃; CH₂F₂; CH₃F; C₂F₄; C₂F₆; C₂H₂F₄; C₃F₆; C₃F₈; or C₅F₈. In other cases, the reactive gas can be any suitable inorganic gas whose decomposed or dissociated fragments can be polymerizable. As some non-limiting examples, the reactive gas can be: any suitable siloxane gas; or any suitable cyclosiloxane gas. As even more specific non-limiting examples, the reactive gas can be any of the following: tetraethylorthosilicate (TEOS); or tetramethylcyclotetrasiloxane. In other words, the present inventors experimentally found that any of the aforementioned gases can be decomposed or fragmented into reactive ions or reactive neutrals that are polymerizable. The aforementioned lists of possible reactive gases are non-limiting. More generally, the reactive gas can be any suitable gas that can be decomposed, dissociated, or otherwise broken-down into polymerizable chemical species. No matter which reactive gas is used, the decomposed precursor 702 can have any suitable properties or characteristics that can be controllably configured by the gas injector 508. As some non-limiting examples, the decomposed precursor 702 can have any suitable flowrate or any suitable concentration.

In any case, the gas injector 508 can spray, stream, or otherwise pump the decomposed precursor 702 toward the cutface 602, such that the decomposed precursor 702 is physically near, physically adjacent to, or otherwise physically in contact with the cutface 602.

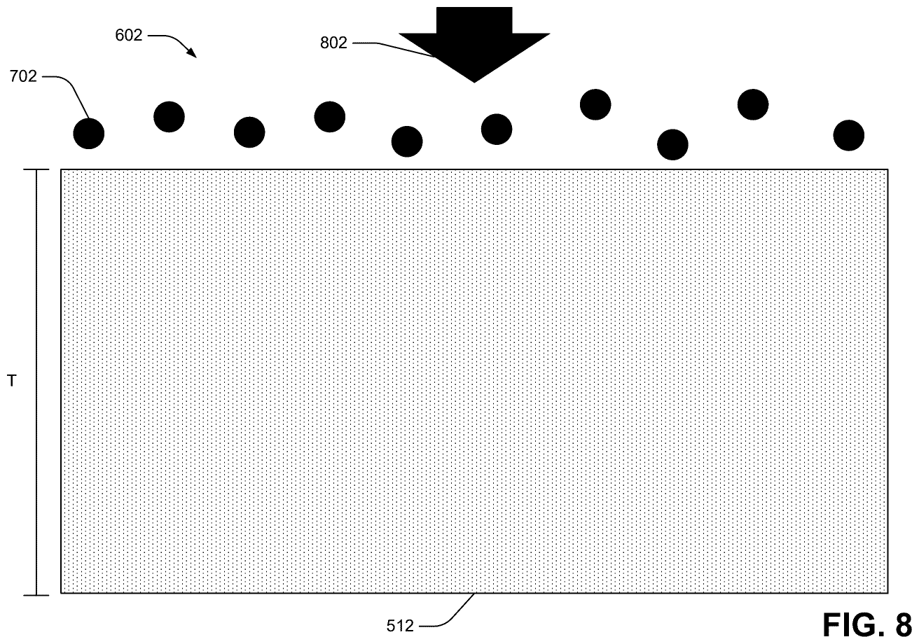

Next, consider FIG. 8. In various aspects, the beam component 522 can electronically instruct, command, or otherwise cause the FIB emitter 506 to continuously, continually, periodically, or otherwise regularly strike or bombard the cutface 602 with an ion beam 802. In various instances, the ion beam 802 can have any suitable characteristics or properties that can be controllably configured by the FIB emitter 506. As some non-limiting examples, the ion beam 802 can be generated by any suitable ion source voltage, can be generated by any suitable ion source current, or can have any suitable focal spot size.

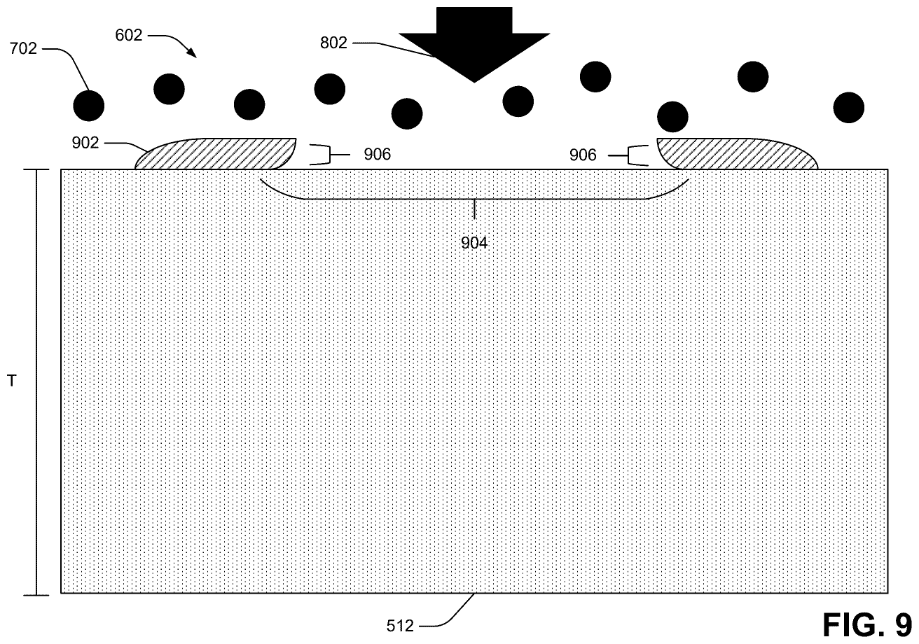

Now, consider FIG. 9. Because the decomposed precursor 702 can be physically near, adjacent to, or in contact with the cutface 602, the ion beam 802 can pass through or otherwise interact with the decomposed precursor 702 as the ion beam 802 is propagating toward the cutface 602. In other words, the decomposed precursor 702 can, while physically present on or near the cutface 602, be exposed to the ion beam 802. In various aspects, such exposure can excite the decomposed precursor 702. That is, the ion beam 802 can transfer or otherwise provide energy to the decomposed precursor 702. In various instances, such excitation (e.g., such beam-to-precursor energy transfer) can trigger, initiate, or otherwise cause the decomposed precursor 702 to undergo a polymerization reaction on the cutface 602. More specifically, the decomposed precursor 702 can, due to receiving energy from the ion beam 802, form polymer chains with itself, and such polymer chains can bond, attach, or otherwise latch onto the cutface 602. Such bonded, attached, or latched polymer chains can be considered as collectively forming a polymer passivation layer 902 on the cutface 602. In other words, the ion beam 802 and the decomposed precursor 702 can together cause the polymer passivation layer 902 to grow on the cutface 602. Note that such growth can be considered as consuming or otherwise depleting at least some of the decomposed precursor 702 that is physically present on, adjacent to, in contact with, or otherwise near the cutface 602. In various cases, such consumption or depletion can be offset by new or fresh amounts of the decomposed precursor 702 supplied or delivered by the gas injector 508.

In various aspects, the ion beam 802 can mill, sputter, eject, or otherwise kinetically remove atoms from whatever surfaces are located within its focus or focal spot size. In the non-limiting example of FIG. 9, a surface 904 can be considered as that portion of the cutface 602 that is encapsulated within the focus or focal spot size of the ion beam 802. Accordingly, the remainder of the cutface 602 can be considered as not being within the focus or focal spot size of the ion beam 802. Note that the polymer passivation layer 902 can grow on some portions of the cutface 602 that are outside of the focus or focal spot size of the ion beam 802 (e.g., that are laterally beyond the surface 904). After all, some portions of the cutface 602 can nevertheless be physically near or adjacent to molecules of the decomposed precursor 702 that are excited by or otherwise receiving energy from the ion beam 802, notwithstanding being outside of the focus or focal spot size. Thus, the polymer passivation layer 902 can grow on portions of the cutface 602 that are outside of the focus or focal spot size but that are nevertheless near the ion beam 802. In contrast, the polymer passivation layer 902 can grow the least (or not at all) on whatever portions of the cutface 602 that are outside of the focus or focal spot size and that are farthest from the ion beam 802.

In any case, the ion beam 802 can mill, sputter, eject, or otherwise kinetically remove atoms from the surface 904 or from whatever portions of the polymer passivation layer 902 that grows on the surface 904. In various aspects, the ion beam 802 can be considered as anisotropic, such that it mills, sputters, ejects, or otherwise kinetically removes atoms at a faster rate from surfaces that are more normal or orthogonal to its axis, and such that it mills, sputters, ejects, or otherwise kinetically removes atoms at a slower rate from surfaces that are more parallel to its axis. Because the surface 904 can, in the non-limiting example of FIG. 9, be substantially perpendicular or orthogonal to (e.g., can be oriented within any suitable threshold margin of 90 degrees with respect to) the axis of the ion beam 802, the ion beam 802 can mill, sputter, eject, or kinetically remove atoms from the surface 904 at a quick rate (e.g., at a sputter yield on the order of 10 to 18 removed atoms per incoming ion). In various instances, the rate at which the ion beam 802 can mill, sputter, eject, or remove atoms from the surface 904 can exceed, outpace, or otherwise be greater than the rate at which the polymer passivation layer 902 can grow on the surface 904. In such case, the ion beam 802 can be considered as preventing the polymer passivation layer 902 from accumulating in any significant or substantial amounts on the surface 904. In other words, any amount of the polymer passivation layer 902 that does manage to accumulate on the surface 904 can be nearly instantaneously milled, sputtered, ejected, or removed by the ion beam 802. Accordingly, FIG. 9 depicts the polymer passivation layer 902 as not accumulating on the surface 904.

In various aspects, the ion beam 802 can mill, sputter, eject, or kinetically remove atoms from surfaces that it impacts, strikes, or bombards. However, in various instances, the ion beam 802 can indirectly mill, sputter, eject, or kinetically remove atoms from surfaces that it does not directly impact, strike, or bombard. In particular, the ion beam 802 can impact, strike, or bombard a first surface, and such impact, striking, or bombardment can cause some ions of the ion beam 802 to scatter, rebound, or ricochet into a second surface that is nearby the first surface. Those scattered, rebounded, or ricocheted ions can thus mill, sputter, eject, or kinetically remove atoms from the second surface, at a rate that depends upon how orthogonal the second surface is to the direction of propagation of those scattered, rebounded, or ricocheted ions (e.g., more orthogonal can correspond to higher sputter yield; more parallel can correspond to lower sputter yield).

So, as the ion beam 802 impacts, strikes, or bombards the surface 904, some ions can scatter and secondarily impact vertical portions of the polymer passivation layer 902 that are near, that encompass, or that surround the surface 904. Such secondary impacts can be more orthogonally or perpendicularly oriented near the bottom of those portions of the polymer passivation layer 902, and such secondary impacts can instead be less orthogonally or perpendicularly oriented near the top of those portions of the polymer passivation layer 902. In other words, the scattered ions that ricochet off the surface 904 and impact the lower, vertically-oriented portions of the polymer passivation layer 902 can strike at steeper or less glancing angles than the scattered ions that instead impact the upper, vertically-oriented portions of the polymer passivation layer 902. Accordingly, as shown by numeral 906, the polymer passivation layer 902 can grow more quickly or to a larger thickness at those upper portions than at those lower portions.

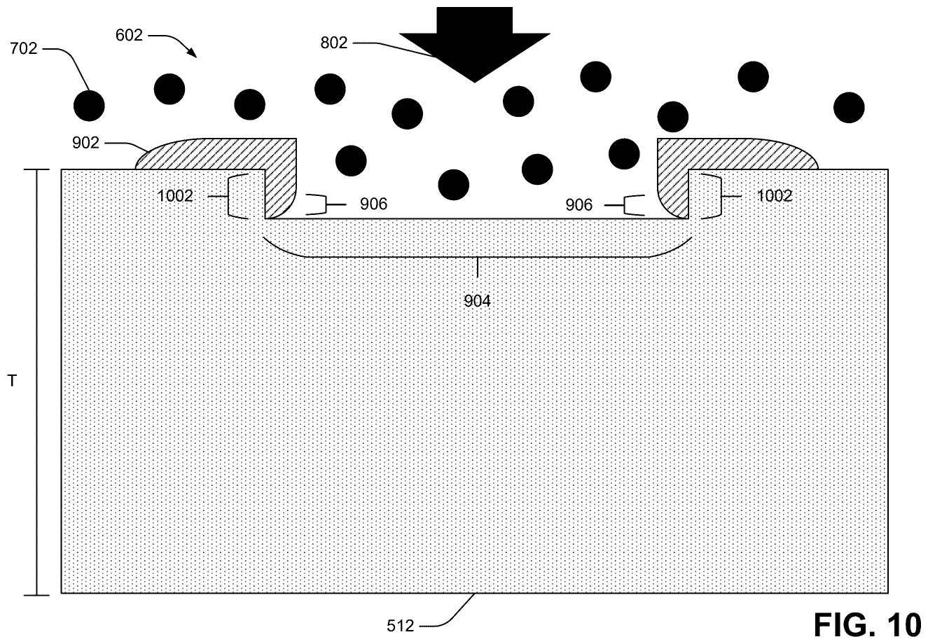

Next, consider FIG. 10. In various embodiments, the emission of the ion beam 802 and the delivery of the decomposed precursor 702 can be coextensively maintained for any suitable span of time. During that span of time, the ion beam 802 can mill, sputter, or otherwise dig into the surface 904, so as to move the surface 904 deeper into the cutface 602. In various aspects, this can form or otherwise reveal a sidewall 1002 on or in the cutface 602. In various instances, as shown, the sidewall 1002 can be substantially parallel to (e.g., can be within any suitable threshold margin of 0 degrees or of 180 degrees with respect to) the axis of the ion beam 802.

In various cases, because the decomposed precursor 702 can be continuously, continually, or otherwise regularly supplied to the cutface 602 by the gas injector 508, the decomposed precursor 702 can become physically near, adjacent to, or in contact with the sidewall 1002 simultaneously as (or mere milli-, micro-, or nano-seconds after) the sidewall 1002 is formed or revealed. Accordingly, just as above, the decomposed precursor 702 can, due to excitation or energy transfer by the ion beam 802, polymerize on the sidewall 1002. In other words, the polymer passivation layer 902 can grow on the sidewall 1002 simultaneously or substantially simultaneously as the sidewall 1002 is uncovered by the ion beam 802. As mentioned above, the ion beam 802 can be anisotropic, such that it mills, sputters, ejects, or otherwise kinetically removes atoms at a faster rate from surfaces that are more normal or orthogonal to its axis, and such that it mills, sputters, ejects, or otherwise kinetically removes atoms at a slower rate from surfaces that are more parallel to its axis. Because the sidewall 1002 can, in the non-limiting example of FIG. 10, be substantially parallel to the axis of the ion beam 802, the ion beam 802 can mill, sputter, eject, or kinetically remove atoms from the sidewall 1002 at a slow rate (e.g., at a sputter yield of merely 1 or 2 removed atoms per incoming ion). In various instances, the rate at which the ion beam 802 can mill, sputter, eject, or remove atoms from the sidewall 1002 can fall short of or otherwise be lesser than the rate at which the polymer passivation layer 902 can grow on the sidewall 1002. In such case, the ion beam 802 can be considered as not being able to prevent the polymer passivation layer 902 from accumulating in significant or substantial amounts on the sidewall 1002. Accordingly, FIG. 10 depicts the polymer passivation layer 902 as accumulating on the sidewall 1002. In this way, the polymer passivation layer 902 can be grown on the sidewall 1002 while (e.g., at the same time as) the ion beam 802 mills the surface 904.

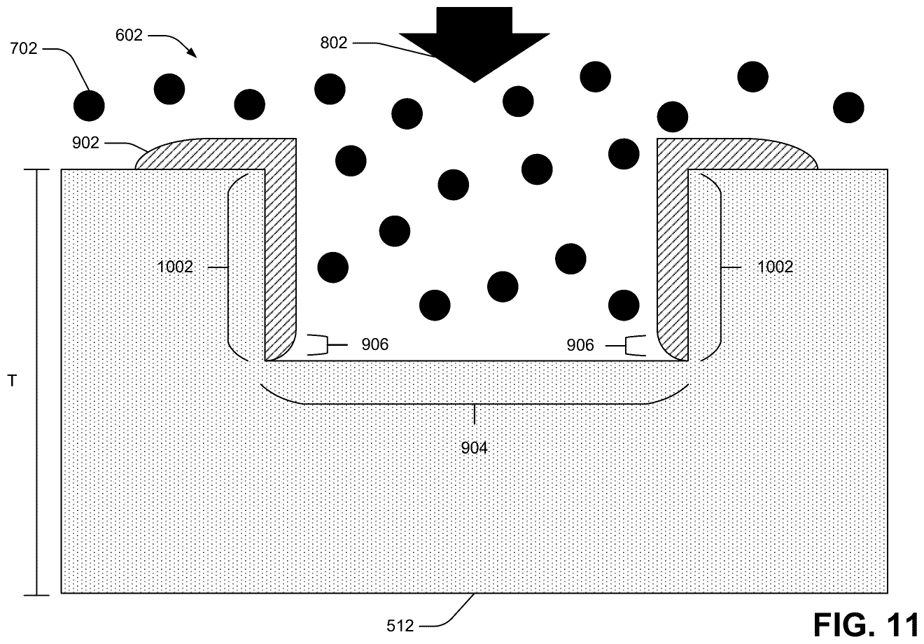

Next, consider FIG. 11. Just as above, the emission of the ion beam 802 and the delivery of the decomposed precursor 702 can be further coextensively maintained for any suitable span of time. During that span of time, the ion beam 802 can continue to mill, sputter, or otherwise dig into the surface 904, so as to move the surface 904 even deeper into the cutface 602. In various aspects, this can form or otherwise reveal new portions of the sidewall 1002 (e.g., the sidewall 1002 can become taller). As explained above, the decomposed precursor 702 can polymerize on those new portions of the sidewall 1002. In other words, the polymer passivation layer 902 can spread to the newly-formed or newly-uncovered portions of the sidewall 1002 as those portions are formed or uncovered.

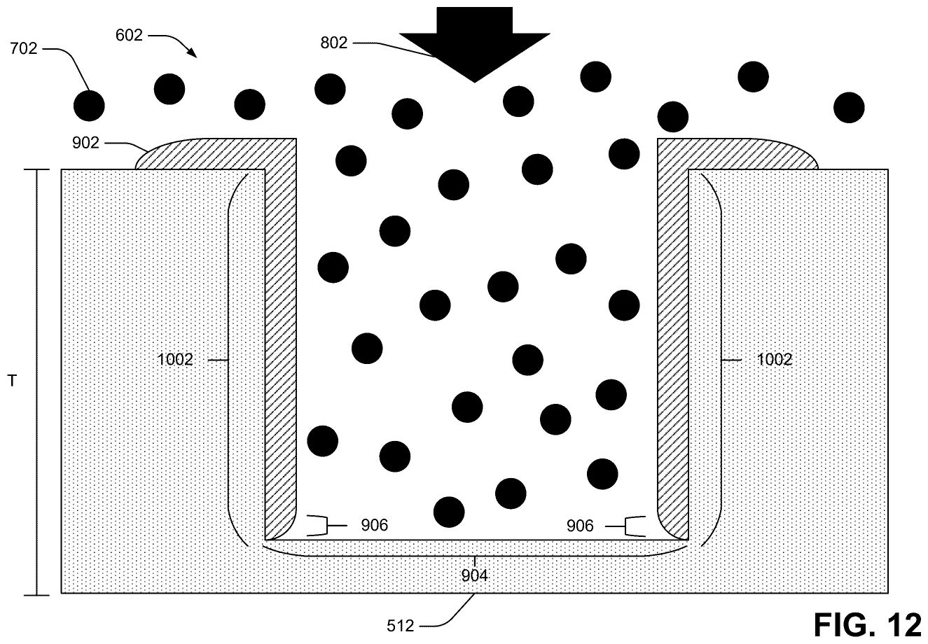

Now, consider FIG. 12. As above, the emission of the ion beam 802 and the delivery of the decomposed precursor 702 can be yet further coextensively maintained for any suitable span of time. During that span of time, the ion beam 802 can continue to mill, sputter, or otherwise dig into the surface 904, so as to move the surface 904 yet even deeper into the cutface 602. In various aspects, this can form or otherwise reveal even more new portions of the sidewall 1002 (e.g., can make the sidewall 1002 even taller). As explained above, the decomposed precursor 702 can polymerize on those even more new portions of the sidewall 1002. Again, the polymer passivation layer 902 can spread to the newly-formed or newly-uncovered portions of the sidewall 1002 as those portions are formed or uncovered.

Note that, because the polymer passivation layer 902 can accumulate on the sidewall 1002 (e.g., can grow on the sidewall 1002 more quickly than the ion beam 802 can remove it), the polymer passivation layer 902 can be considered as protecting, shielding, or otherwise safeguarding the sidewall 1002 from unwanted milling, sputtering, backscattering, curtaining, erosion, or other damage that might otherwise be caused by the ion beam 802 or by beam tails of the ion beam 802.

As a non-limiting example, the beam tails of the ion beam 802 can become progressively more likely to collide or otherwise interact with the sidewall 1002 as the surface 904 is moved or dug deeper into the cutface 602. Such beam tail collision or interaction could cause curtaining or other damage to the sidewall 1002. However, because the sidewall 1002 can be covered by the polymer passivation layer 902, the beam tails of the ion beam 802 can be unable to collide or otherwise interact with the sidewall 1002. Instead, the beam tails of the ion beam 802 can collide or otherwise interact with the portions of the polymer passivation layer 902 that cover the sidewall 1002. Thus, any curtaining, erosion, or damage that the beam tails would have imparted to the sidewall 1002 can instead be imparted to those portions of the polymer passivation layer 902. In situations where the decomposed precursor 702 is supplied continuously, continually, or otherwise regularly to the cutface 602, those portions of the polymer passivation layer 902 can be replenished, recharged, or otherwise healed by polymerization of the newly, freshly, or most-recently supplied instances of the decomposed precursor 702.

As another non-limiting example, as the ion beam 802 strikes or bombards the surface 904, various ions can scatter or ricochet toward the sidewall 1002. If such scattered or ricocheted ions were to impact or collide with the sidewall 1002, milling, sputtering, or other damage could befall the sidewall 1002. However, because the sidewall 1002 can be covered by the polymer passivation layer 902, the scattered or ricocheted ions can be unable to collide or otherwise interact with the sidewall 1002. Instead, the scattered or ricocheted ions can collide or otherwise interact with the portions of the polymer passivation layer 902 that cover the sidewall 1002. Thus, any milling, sputtering, or damage that the scattered or ricocheted ions would have imparted to the sidewall 1002 can instead be imparted to those portions of the polymer passivation layer 902. Again, in situations where the decomposed precursor 702 is supplied continuously, continually, or otherwise regularly to the cutface 602, those portions of the polymer passivation layer 902 can be replenished, recharged, or healed by polymerization of the newly, freshly, or most-recently supplied instances of the decomposed precursor 702.

Note that scattered or ricocheted ions that are directed toward the lower or bottom portions of the sidewall 1002 can be considered as having steeper or less glancing angles and thus as having higher sputter yields. In contrast, scattered or ricocheted ions that are instead directed toward the upper or top portions of the sidewall 1002 can be considered as having less steep or more glancing angles and thus as having lower sputter yields. Accordingly, the polymer passivation layer 902 can be considered as growing more slowly (or to smaller thicknesses) at the lower or bottom portions of the sidewall 1002 than at the upper or top portions of the sidewall 1002. This is indicated by numeral 906 in FIGS. 10-12.

In various aspects, the surface 904 and the sidewall 1002 can be considered as forming a trench in the cutface 602. In various instances, that trench can be milled or dug to any suitable aspect ratio. Because the polymer passivation layer 902 can be grown during such milling, the sidewall 1002 can be preserved or protected from damage that would have otherwise been caused by such milling. In various cases, any other suitable number of trenches can be milled or dug into the specimen 512 in combination with the trench formed by the surface 904 and the sidewall 1002, so as to fabricate or extract any suitable high aspect ratio structure that is desired.

In various aspects, once a desired high aspect ratio structure is fabricated on or extracted from the specimen 512, the etch component 526 can electronically instruct, command, or otherwise cause the etcher 510 to bathe, douse, cover, or spray the cutface 602 or the extracted high aspect ratio structure with any suitable etchant that can dissolve polymers but not semiconductor substrates or wafers. In various aspects, the etchant can be any suitable dry or wet etching solutions. Some non-limiting examples of a dry etchant can be: a plasma cleaner; an oxygen ion beam (e.g., whether focused or defocused like a flood gun); or a remote oxygen plasma. Some non-limiting examples of a wet etchant can be: piranha solution (e.g., H₂SO₄+H₂O₂); a buffered oxide etchant (e.g., HF+NH₄F); SC1 solution (e.g., NH₄OH+H₂O₂); SC2 solution (e.g., HCl+H₂O₂); or phosphoric acid. It is to be understood that the specific machinery or hardware (e.g., specific types of piping, pumps, conduits, nozzles, or tanks) that make up the etcher 510 can depend upon or otherwise vary with the specific type of etchant that the etcher 510 is configured to deliver (e.g., transporting oxygen plasma can require different delivery hardware than transporting piranha solution). In any case, bathing, dousing, covering, or spraying the cutface 602 or the extracted high aspect ratio structure with the etchant can cause remnants or remaining portions of the polymer passivation layer 902 to be removed from the cutface 602 or from the extracted high aspect ratio structure. After such removal, the cutface 602 or the extracted high aspect ratio structure can be considered as being ready for any suitable follow-on or downstream analysis, fabrication procedure, or use.

Note that, in various aspects, various factors can influence or otherwise affect how quickly or slowly the polymer passivation layer 902 grows on various portions of the cutface 602. As a non-limiting example, such factors can include temperature of the specimen 512. As another non-limiting example, such factors can include energy level of the ion beam 802. As even another non-limiting example, such factors can include concentration, volume, or mass flowrate of the decomposed precursor 702. As still another non-limiting example, such factors can include thickness of a given portion of the polymer passivation layer 902 (e.g., if a given portion of the polymer passivation layer 902 that covers the sidewall 1002 grows too thick, that given portion can protrude farther into the focal center of the ion beam 802, which can increase the sputter yield of the ion beam 802 with respect to that given portion and thus slow or stop the growth of that given portion; in other words, there can be a sidewall polymer thickness at which a milling-growth equilibrium is reached).

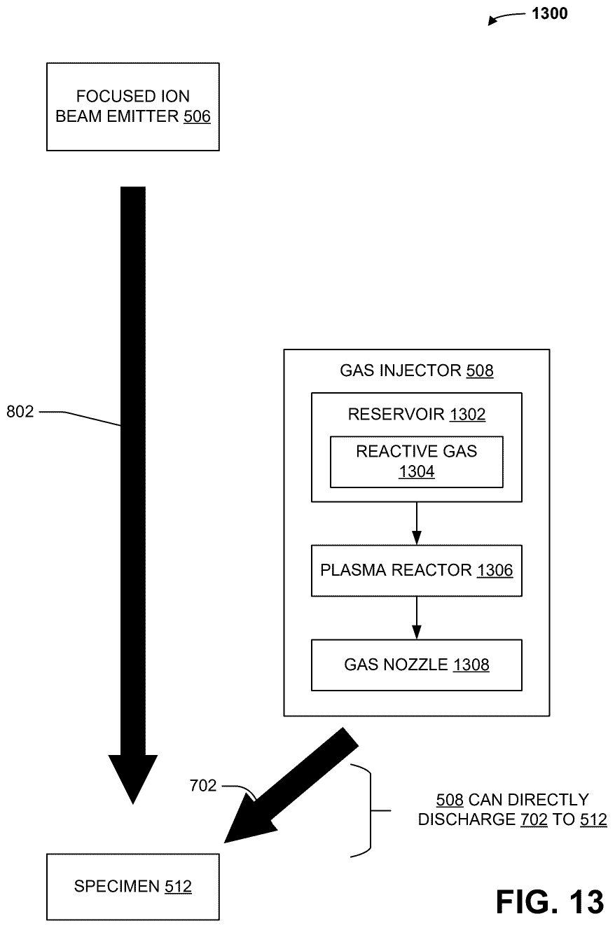

FIGS. 13-15 illustrate example, non-limiting block diagrams showing various precursor delivery techniques for growing a protective polymer layer during milling in accordance with one or more embodiments described herein.

First, consider FIG. 13. In various embodiments, as shown, the gas injector 508 can comprise a reservoir 1302, a plasma reactor 1306, or a gas nozzle 1308.

In various aspects, the reservoir 1302 can be any suitable tank or container that can house or otherwise hold a reactive gas 1304. As some non-limiting examples, the reservoir 1302 can be or otherwise comprise a ceramic crucible, a PTFE enclosure, or a non-reactive metal or alloy enclosure. In various instances, the reactive gas 1304 can be whatever reactive gas from which the decomposed precursor 702 can be derived or obtained. As a non-limiting example, the reactive gas 1304 can be any suitable organic fluoride gas (e.g., C₂F₆; CF₄; C₄F₈).

In various cases, the plasma reactor 1306 can receive (e.g., via actuation of any suitable valves, motors, or pumps) any suitable amount of the reactive gas 1304 from the reservoir 1302. In some instances, the plasma reactor 1306 can receive a discrete amount of the reactive gas 1304. In other instances, the plasma reactor 1306 can receive a continuous flow of the reactive gas 1304. In various aspects, the plasma reactor 1306 can apply (e.g., via any suitable electrodes, coils, waveguides, magnetrons, or microwave components) any suitable electric or electromagnetic fields to whatever amount of the reactive gas 1304 that is received from the reservoir 1302. As a non-limiting example, such electric or electromagnetic fields can have frequencies on the order of mega-Hertz or giga-Hertz. In any case, such electric or electromagnetic fields can excite or transfer energy to whatever amount of the reactive gas 1304 that is received from the reservoir 1302, thereby causing that amount of the reactive gas 1304 to decompose or breakdown into reactive neutrals and reactive ions. In various aspects, the decomposed precursor 702 can be either or both of such reactive neutrals and reactive ions.

In some situations, the gas injector 508 can be positioned or located within the scientific instrument 502 such that there is an optical line-of-sight between the gas injector 508 and the specimen 512 (e.g., to the stage 325). In such cases, the gas nozzle 1308 can spray, atomize, pump, or otherwise discharge the decomposed precursor 702 (e.g., the reactive neutrals or the reactive ions formed by the plasma reactor 1306) toward or onto the cutface 602 of the specimen 512. Accordingly, as mentioned above, the FIB emitter 506 can strike or bombard the cutface 602 with the ion beam 802, and such striking or bombardment can cause the decomposed precursor 702 to polymerize, thereby yielding the polymer passivation layer 902.

In other words, FIG. 13 shows a non-limiting example precursor delivery technique, in which the gas injector 508 produces the decomposed precursor 702 via the plasma reactor 1306, and in which the gas injector 508 sprays the decomposed precursor 702 directly onto the specimen 512.

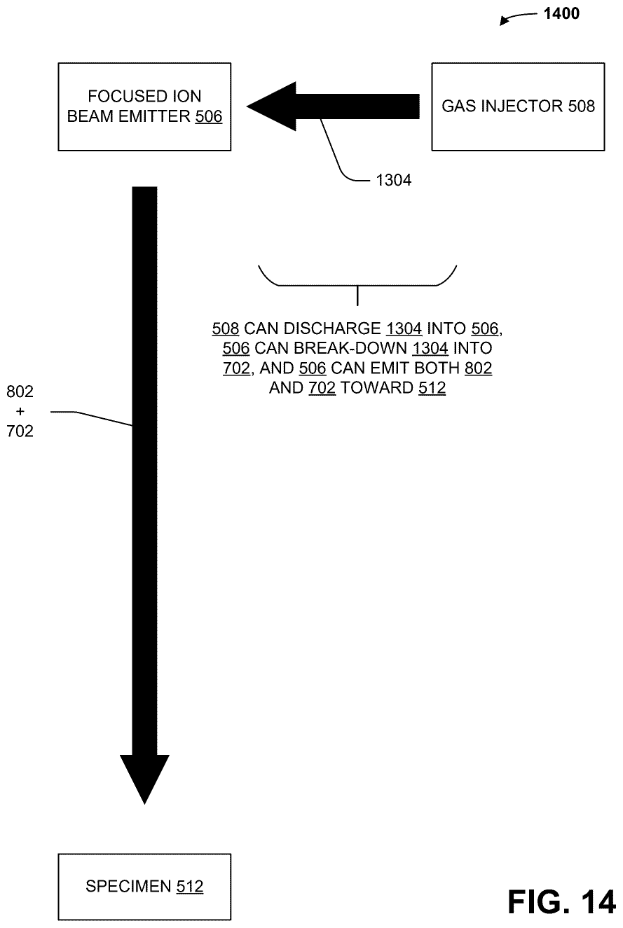

Next, consider FIG. 14. In various embodiments, rather than being positioned or located within the scientific instrument 502 such that it has an optical line-of-sight to the specimen 512, the gas injector 508 can instead be positioned or located within the scientific instrument 502 such that it has no optical line-of-sight to the specimen 512. In such cases, the gas injector 508 can lack or omit the plasma reactor 1306 and can spray, atomize, pump, or otherwise discharge the reactive gas 1304 into the FIB emitter 506. More specifically, the gas injector 508 can deliver the reactive gas 1304 to or into an ion source (e.g., 310) of the FIB emitter 506. In various aspects, when the ion source of the FIB 506 generates or otherwise creates the ion beam 802, such generation or creation can be considered as an energizing event that decomposes, dissociates, or otherwise breaks-down the reactive gas 1304 into the decomposed precursor 702 (e.g., into reactive neutrals and reactive ions). In various instances, the ion beam 802 can then carry the decomposed precursor 702 (e.g., can carry the reactive ions formed by the ion source of the FIB emitter 506) toward or to the cutface 602 of the specimen 512. Accordingly, as described above, the decomposed precursor 702 can polymerize into to the polymer passivation layer 902.

In other words, FIG. 14 shows a non-limiting example precursor delivery technique, in which the gas injector 508 indirectly delivers the decomposed precursor 702 to the specimen 512 by spraying the reactive gas 1304 into the FIB emitter 506.

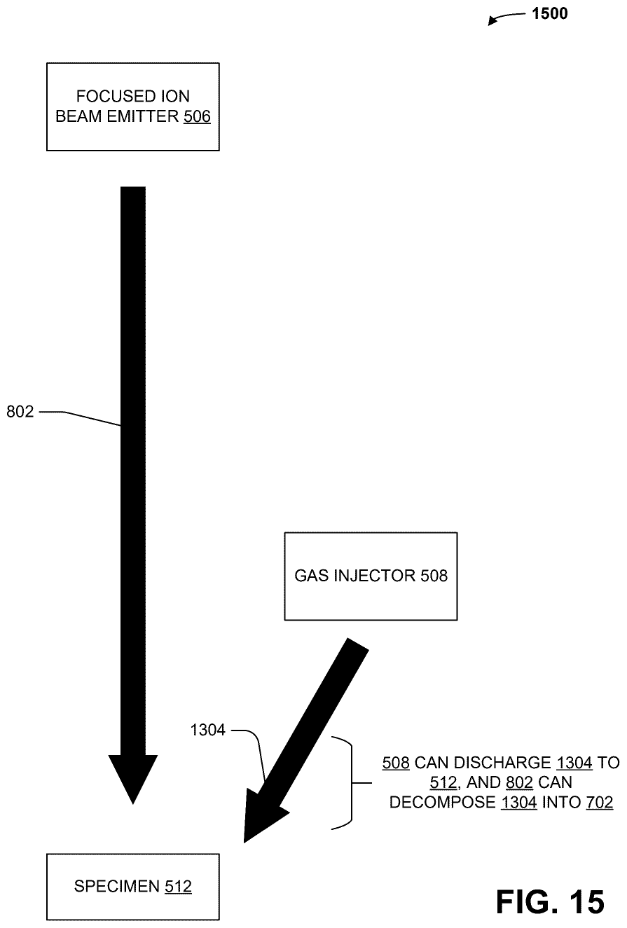

Now, consider FIG. 15. In some embodiments, the gas injector 508 can lack or omit the plasma reactor 1306. Equivalently, the gas injector 508 can power-down or deactivate the plasma reactor 1306. In any of such cases, the gas nozzle 1308 can receive (e.g., via actuation of any suitable valves, motors, or pumps) any suitable amount of the reactive gas 1304 from the reservoir 1302, and the gas nozzle 1308 can spray, atomize, pump, or otherwise discharge that portion of the reactive gas 1304 to the cutface 602 of the specimen 512. In such situations, the reactive gas 1304 can be physically near, physically adjacent to, or otherwise physically in contact with the cutface 602, and the ion beam 802 can thus pass through the reactive gas 1304 on its way to the cutface 602. In various aspects, ion beam 802 can excite or otherwise supply energy to the reactive gas 1304, which can cause the reactive gas 1304 to breakdown into the decomposed precursor 702 (e.g., into reactive ions and reactive neutrals). Then, as described above, the ion beam 802 can cause the decomposed precursor 702 to polymerize into the polymer passivation layer 902. That is, the ion beam 802 can, in some cases, be considered as not only supplying the excitation energy that causes the decomposed precursor 702 to polymerize, but as also supplying the preliminary excitation energy that causes the reactive gas 1304 to be converted into the decomposed precursor 702 in the first place.

In other words, FIG. 15 shows a non-limiting example precursor delivery technique, in which the gas injector 508 indirectly delivers the decomposed precursor 702 to the specimen 512 by spraying the reactive gas 1304 directly onto the specimen 512.

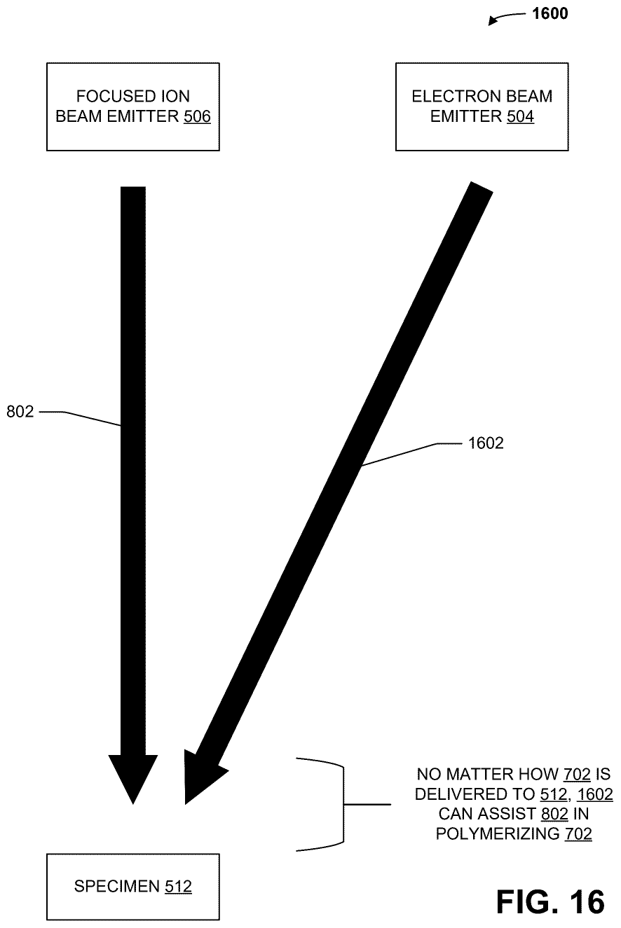

FIG. 16 illustrates an example, non-limiting block diagram showing how an electron beam can be used in conjunction with a focused ion beam to grow a protective polymer layer during milling in accordance with one or more embodiments described herein.

No matter how the decomposed precursor 702 is specifically delivered or transported to the cutface 602 of the specimen 512 (e.g., delivered as explained with respect to FIG. 13; delivered as explained with respect to FIG. 14; or delivered as explained with respect to FIG. 15), the ion beam 802 can be considered as both milling the cutface 602 and as triggering or initiating growth of the polymer passivation layer 902 so as to protect the sidewall 1002 during such milling. In various embodiments, the beam component 522 can electronically instruct, command, or otherwise cause the e-beam emitter 504 to continuously, continually, periodically, or otherwise regularly strike or bombard the cutface 602 with an electron beam 1602. In various instances, the electron beam 1602 can have any suitable characteristics or properties that can be controllably configured by the e-beam emitter 504. As some non-limiting examples, the electron beam 1602 can be generated by any suitable electron source voltage, can be generated by any suitable electron source current, or can have any suitable focal spot size. In any case, the beam component 522 can cause the e-beam emitter 504 to emit the electron beam 1602 simultaneously as the FIB emitter 506 emits the ion beam 802. Accordingly, the ion beam 802 and the electron beam 1602 can be considered as striking or bombarding the cutface 602 simultaneously as each other. In various instances, the electron beam 1602 can thus be considered as helping or assisting the ion beam 802 in exciting the decomposed precursor 702 (or in exciting the reactive gas 1304, in situations where the gas injector 508 sprays the reactive gas 1304 directly onto the specimen 512). In other words, whatever portions of the decomposed precursor 702 that polymerize on the cutface 602 can be considered as receiving excitation energy not just from the ion beam 802 but also from the electron beam 1602. In such embodiments, the electron beam 1602 can be considered as reducing the workload of the ion beam 802 or as otherwise helping to expedite the polymerization of the decomposed precursor 702.

Various embodiments described herein involve growing a protective polymer shield on sidewalls of a specimen during, while, or otherwise simultaneously as the specimen is being milled. As described herein, such embodiments can be considered as leveraging the innovative and counter-intuitive realization of the present inventors that an ion beam that facilitates milling of the specimen can, at the same time as such milling, trigger or initiate sidewall polymerization. In this way, high aspect ratio structures can be milled into or out of the specimen in a time-efficient manner and without significantly harming the sidewalls of such structures. Contrast this with existing techniques which: leave the sidewalls vulnerable to undercutting; or otherwise require time-consuming cyclic-deposition of polymer passivation layers. Accordingly, various embodiments described herein can be considered as inventive, innovative, practical applications in the field of integrated circuit fabrication.

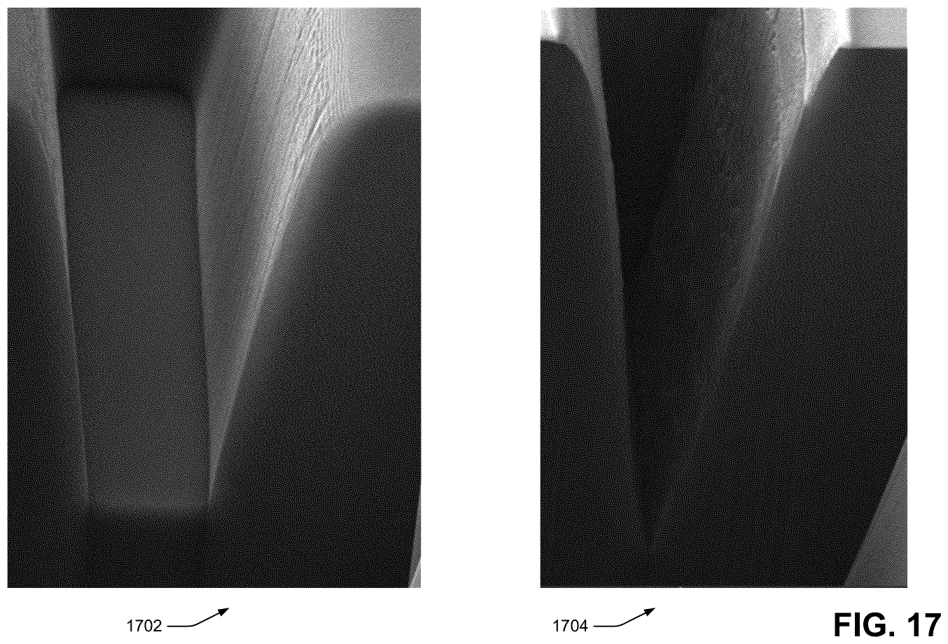

Indeed, the present inventors conducted various experiments to validate benefits of various embodiments described herein. Some results of those experiments are shown in FIGS. 17-19.

First, consider FIG. 17. The present inventors performed an experiment that involved fabricating 83-degree trenches on a semiconductor substrate via xenon milling ions having a beam voltage of 30 keV and a beam current of 2.5 micro-amps. A first trench was fabricated without utilizing protective polymers via milling-excitation. A scanning electron microscopy image 1702 depicts that first trench. A second trench was fabricated in accordance with various embodiments described herein. A scanning electron microscopy image 1704 depicts that second trench.

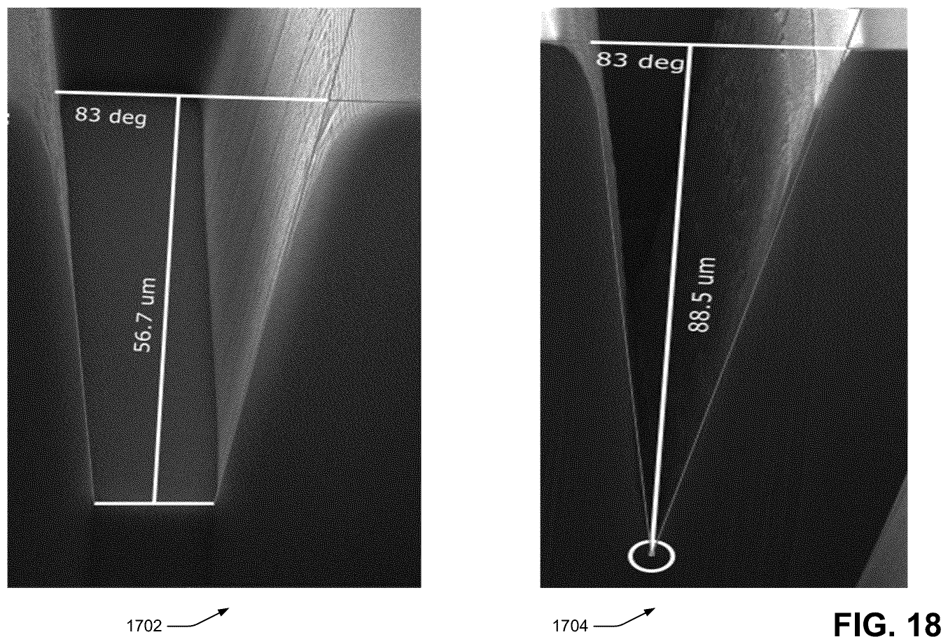

The second trench was able to be milled significantly deeper than the first trench. Indeed, as shown in FIG. 18, the second trench had a depth of 88.5 micrometers, whereas the first trench had a depth of only 56.7 micrometers, for the same amount of milling time.

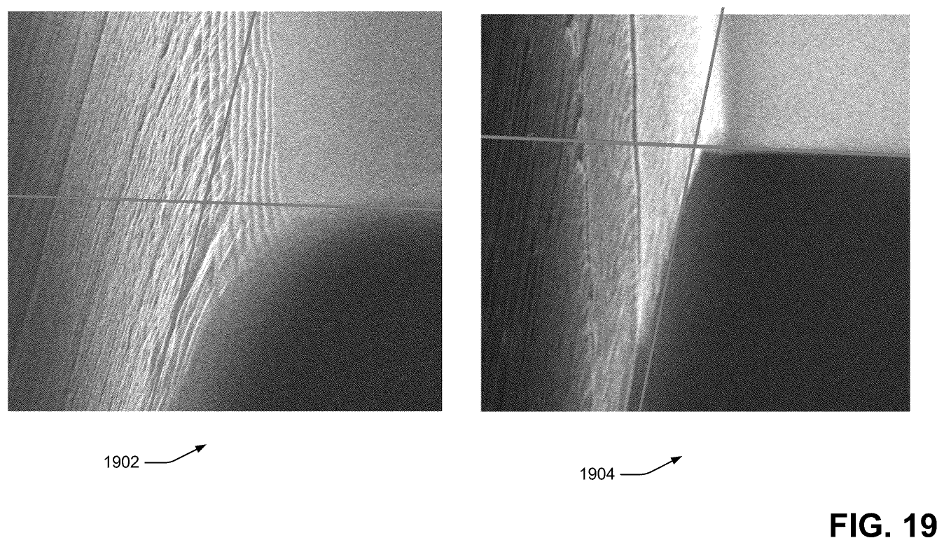

Furthermore, the second trench suffered significantly less sidewall damage as compared to the first trench. Indeed, FIG. 19 shows a close-up view 1902 of the upper right corner of the first trench, and FIG. 19 also shows a close-up view 1904 of the upper right corner of the second trench. As can be seen, the sidewalls of the first trench have significantly more curtaining than the sidewalls of the second trench. As can also be seen, the top edges of the sidewalls of the first trench are much more sloped and less tight than the top edges of the sidewalls of the second trench. In other words, the sidewalls of the first trench suffered significantly more erosion than the sidewalls of the second trench.

That is, these experimental results demonstrate that protective polymer growth via milling-excitation can lead to the formation of deeper structures (e.g., higher aspect ratios) with less sidewall damage (e.g., less erosion, less curtaining). In other words, protective polymer growth via milling-excitation can be considered as increasing the anisotropy of milling. Accordingly, various embodiments described herein certainly constitute a concrete and tangible technical improvement in the field of integrated circuit fabrication.

The scientific instrument systems, methods, or techniques disclosed herein may include interactions with a human user (e.g., via a user local computing device 2220 discussed herein with reference to FIG. 22). These interactions may include providing information to the user (e.g., information regarding the operation of a scientific instrument such as the scientific instrument 2210 of FIG. 22, information regarding a sample being analyzed or other test or measurement performed by a scientific instrument, information retrieved from a local or remote database, or other information) or providing an option for a user to input commands (e.g., to control the operation of a scientific instrument such as the scientific instrument 2210 of FIG. 22, or to control the analysis of data generated by a scientific instrument), queries (e.g., to a local or remote database), or other information. In some embodiments, these interactions may be performed through a graphical user interface (GUI) that includes a visual display on a display device (e.g., a display device 2110 discussed herein with reference to FIG. 21) that provides outputs to the user and/or prompts the user to provide inputs (e.g., via one or more input devices, such as a keyboard, mouse, trackpad, or touchscreen, included in other I/O devices 2112 discussed herein with reference to FIG. 21). The scientific instrument systems, methods, or techniques disclosed herein may include any suitable GUIs for interaction with a user.

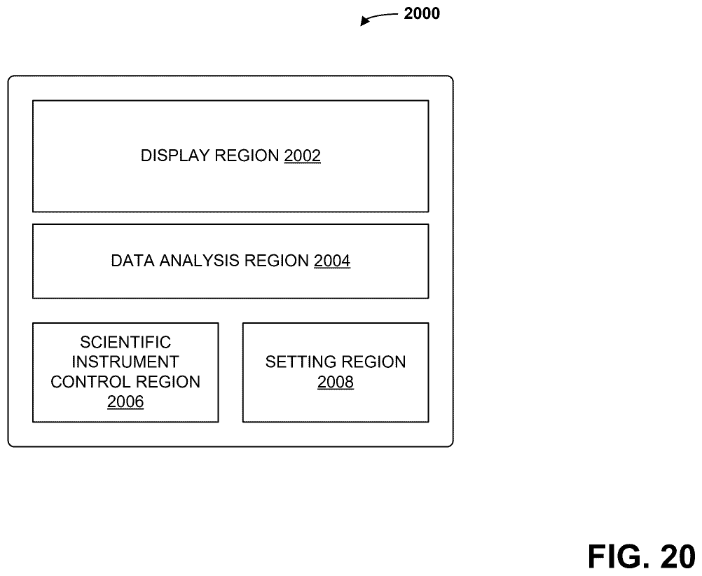

FIG. 20 depicts an example graphical user interface 2000 (hereafter “GUI 2000”) that can be used in the performance of some or all of the support methods or techniques disclosed herein, in accordance with various embodiments. In various aspects, the GUI 2000 can be provided on any suitable electronic display (e.g., a display device 2110 discussed herein with reference to FIG. 21) of a computing device (e.g., a computing device 2100 discussed herein with reference to FIG. 21) of a scientific instrument support system (e.g., a scientific instrument support system 2200 discussed herein with reference to FIG. 22), and a user or technician can interact with the GUI 2000 using any suitable input device (e.g., any of other I/O devices 2112 discussed herein with reference to FIG. 21) and input technique (e.g., movement of a cursor, motion capture, facial recognition, gesture detection, voice recognition, actuation of buttons).

The GUI 2000 can include a data display region 2002, a data analysis region 2004, a scientific instrument control region 2006, and a setting region 2008. The particular number and arrangement of regions depicted in FIG. 20 is merely illustrative, and any number and arrangement of regions, including any desired features, can be included in other embodiments of the GUI 2000.

The data display region 2002 can display data generated by a scientific instrument (e.g., a scientific instrument 2210 discussed herein with reference to FIG. 22).

The data analysis region 2004 can display any suitable data analysis results (e.g., the results of analyzing the data illustrated in the data display region 2002 or other data). In some embodiments, the data display region 2002 and the data analysis region 2004 can be combined in the GUI 2000 (e.g., to include both data output from a scientific instrument and some analysis of the data in a common graph or region).

The scientific instrument control region 2006 can include options that allow a user or technician to control a scientific instrument (e.g., the scientific instrument 2210 discussed herein with reference to FIG. 22). For example, the scientific instrument control region 2006 can include configurable parameters that govern operation of such scientific instrument (e.g., configurable parameters that govern voltages or electric currents of the scientific instrument, that govern interior temperatures of the scientific instrument, or that govern fluid flowrates of the scientific instrument).

The setting region 2008 can include options that allow a user or technician to control any features or functions of the GUI 2000 (or of other GUIs) or to perform common computing operations with respect to the data display region 2002 and the data analysis region 2004 (e.g., saving data on a storage device, such as the storage device 2104 discussed herein with reference to FIG. 21, sending data to another user, labeling data).

As noted above, the scientific instrument module 102 can be implemented by one or more computing devices. FIG. 21 is a block diagram of a computing device 2100 that can perform some or all of the scientific instrument methods or techniques disclosed herein, in accordance with various embodiments. In some embodiments, the scientific instrument module 102 can be implemented by a single instance of the computing device 2100 or by multiple instances of the computing device 2100. Further, as discussed below, the computing device 2100 (or multiple instances thereof) that implements the scientific instrument module 102 can be part of one or more of a scientific instrument 2210, a user local computing device 2220, a service local computing device 2230, or a remote computing device 2240 of FIG. 22.

The computing device 2100 is illustrated as having a number of components, but any one or more of these components can be omitted or duplicated, as suitable for the application and setting. In some embodiments, some or all of the components included in the computing device 2100 can be attached to one or more motherboards and enclosed in a housing (e.g., including plastic, metal, or other materials). In some embodiments, some these components can be fabricated onto a single system-on-a-chip (SoC) (e.g., an SoC may include one or more instances of a processing device 2102 and one or more instances of a storage device 2104). Additionally, in various embodiments, the computing device 2100 can omit one or more of the components illustrated in FIG. 21, but can include interface circuitry (not shown) for coupling to the one or more omitted components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 2100 can omit a display device 2110, but can include display device interface circuitry (e.g., a connector and driver circuitry) to which a display device 2110 can be coupled.

The computing device 2100 can include a processing device 2102 (e.g., one or more processing devices). As used herein, the term “processing device” can refer to any device or portion of a device that processes electronic data from registers or memory to transform that electronic data into other electronic data that may be stored in registers or memories. The processing device 2102 can include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 2100 can include a storage device 2104 (e.g., one or more storage devices). The storage device 2104 can include one or more memory devices such as random access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some embodiments, the storage device 2104 can include memory that shares a die with a processing device 2102. In such an embodiment, the memory may be used as cache memory and may include embedded dynamic random access memory (eDRAM) or spin transfer torque magnetic random access memory (STT-MRAM), for example. In some embodiments, the storage device 2104 can include non-transitory computer readable media having instructions thereon that, when executed by one or more processing devices (e.g., the processing device 2102), cause the computing device 2100 to perform any appropriate ones of or portions of the methods disclosed herein.

The computing device 2100 can include an interface device 2106 (e.g., one or more instances of the interface device 2106). The interface device 2106 can include one or more communication chips, connectors, or other hardware and software to govern communications between the computing device 2100 and other computing devices. For example, the interface device 2106 can include circuitry for managing wireless communications for the transfer of data to and from the computing device 2100. The term “wireless” and its derivatives may be used to describe circuits, devices, systems, methods, techniques, or communications channels that may communicate data through the use of modulated electromagnetic radiation through a nonsolid medium. The term does not imply that the associated devices do not contain any wires, although in some embodiments they might not. Circuitry included in the interface device 2106 for managing wireless communications may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”)). In some embodiments, circuitry included in the interface device 2106 for managing wireless communications can operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some embodiments, circuitry included in the interface device 2106 for managing wireless communications can operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some embodiments, circuitry included in the interface device 2106 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some embodiments, the interface device 2106 may include one or more antennas (e.g., one or more antenna arrays) to receipt and/or transmission of wireless communications.

In some embodiments, the interface device 2106 can include circuitry for managing wired communications, such as electrical, optical, or any other suitable communication protocols. For example, the interface device 2106 can include circuitry to support communications in accordance with Ethernet technologies. In some embodiments, the interface device 2106 can support both wireless and wired communication, or can support multiple wired communication protocols or multiple wireless communication protocols. For example, a first set of circuitry of the interface device 2106 may be dedicated to shorter-range wireless communications such as Wi-Fi or Bluetooth, and a second set of circuitry of the interface device 2106 may be dedicated to longer-range wireless communications such as global positioning system (GPS), EDGE, GPRS, CDMA, WiMAX, LTE, EV-DO, or others. In some embodiments, a first set of circuitry of the interface device 2106 can be dedicated to wireless communications, and a second set of circuitry of the interface device 2106 can be dedicated to wired communications.

The computing device 2100 can include battery/power circuitry 2108. The battery/power circuitry 2108 can include one or more energy storage devices (e.g., batteries or capacitors) or circuitry for coupling components of the computing device 2100 to an energy source separate from the computing device 2100 (e.g., alternating current line power).

The computing device 2100 can include a display device 2110 (e.g., multiple display devices). The display device 2110 can include any visual indicators, such as a heads-up display, a computer monitor, a projector, a touchscreen display, a liquid crystal display (LCD), a light-emitting diode display, or a flat panel display.

The computing device 2100 can include other input/output (I/O) devices 2112. The other I/O devices 2112 can include one or more audio output devices (e.g., speakers, headsets, earbuds, alarms), one or more audio input devices (e.g., microphones or microphone arrays), location devices (e.g., GPS devices in communication with a satellite-based system to receive a location of the computing device 2100), audio codecs, video codecs, printers, sensors (e.g., thermocouples or other temperature sensors, humidity sensors, pressure sensors, vibration sensors, accelerometers, gyroscopes), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 2100 can have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer), a desktop computing device, or a server computing device or other networked computing component.

One or more computing devices implementing any of the scientific instrument modules, methods, or techniques disclosed herein may be part of a scientific instrument support system. FIG. 22 is a block diagram of an example scientific instrument support system 2200 in which some or all of the scientific instrument support methods disclosed herein may be performed, in accordance with various embodiments. The scientific instrument modules, methods, or techniques disclosed herein (e.g., the scientific instrument module 102, the method 200, the system 514) can be implemented by one or more of a scientific instrument 2210, a user local computing device 2220, a service local computing device 2230, or a remote computing device 2240 of the scientific instrument support system 2200.

Any of the scientific instrument 2210, the user local computing device 2220, the service local computing device 2230, or the remote computing device 2240 can include any of the embodiments of the computing device 2100, and any of the scientific instrument 2210, the user local computing device 2220, the service local computing device 2230, or the remote computing device 2240 can take the form of any appropriate ones of the embodiments of the computing device 2100.

The scientific instrument 2210, the user local computing device 2220, the service local computing device 2230, or the remote computing device 2240 may each include a processing device 2202, a storage device 2204, and an interface device 2206. The processing device 2202 may take any suitable form, including any form of the processing device 2102, and the processing devices 2202 included in different ones of the scientific instrument 2210, the user local computing device 2220, the service local computing device 2230, or the remote computing device 2240 may take the same form or different forms. The storage device 2204 may take any suitable form, including any form of the storage device 2104, and the storage devices 2204 included in different ones of the scientific instrument 2210, the user local computing device 2220, the service local computing device 2230, or the remote computing device 2240 may take the same form or different forms. The interface device 2206 may take any suitable form, including any form of the interface device 2106, and the interface devices 2206 included in different ones of the scientific instrument 2210, the user local computing device 2220, the service local computing device 2230, or the remote computing device 2240 may take the same form or different forms.

The scientific instrument 2210, the user local computing device 2220, the service local computing device 2230, and the remote computing device 2240 can be in communication with other elements of the scientific instrument support system 2200 via communication pathways 2208. The communication pathways 2208 may communicatively couple the interface devices 2206 of different ones of the elements of the scientific instrument support system 2200, as shown, and may be wired or wireless communication pathways (e.g., in accordance with any of the communication techniques discussed herein with reference to the interface device 2106). The particular scientific instrument support system 2200 depicted in FIG. 22 includes communication pathways between each pair of the scientific instrument 2210, the user local computing device 2220, the service local computing device 2230, and the remote computing device 2240, but this “fully connected” implementation is merely illustrative, and in various embodiments, various ones of the communication pathways 2208 may be absent. For example, in some embodiments, a service local computing device 2230 can lack a direct communication pathway 2208 between its interface device 2206 and the interface device 2206 of the scientific instrument 2210, but can instead communicate with the scientific instrument 2210 via the communication pathway 2208 between the service local computing device 2230 and the user local computing device 2220 and the communication pathway 2208 between the user local computing device 2220 and the scientific instrument 2210.

The scientific instrument 2210 may include any appropriate scientific instrument, such as the scientific instrument 302.

The user local computing device 2220 can be a computing device (e.g., in accordance with any of the embodiments of the computing device 2100) that is local to a user of the scientific instrument 2210. In some embodiments, the user local computing device 2220 may also be local to the scientific instrument 2210, but this need not be the case; for example, a user local computing device 2220 that is in a user's home or office may be remote from, but in communication with, the scientific instrument 2210 so that the user may use the user local computing device 2220 to control or access data from the scientific instrument 2210. In some embodiments, the user local computing device 2220 may be a laptop, smartphone, or tablet device. In some embodiments the user local computing device 2220 can be a portable computing device.

The service local computing device 2230 can be a computing device (e.g., in accordance with any of the embodiments of the computing device 2100) that is local to an entity that services the scientific instrument 2210. For example, the service local computing device 2230 may be local to a manufacturer of the scientific instrument 2210 or to a third-party service company. In some embodiments, the service local computing device 2230 can communicate with the scientific instrument 2210, the user local computing device 2220, or the remote computing device 2240 (e.g., via a direct communication pathway 2208 or via multiple “indirect” communication pathways 2208, as discussed above) to receive data regarding the operation of the scientific instrument 2210, the user local computing device 2220, or the remote computing device 2240 (e.g., the results of self-tests of the scientific instrument 2210, calibration coefficients used by the scientific instrument 2210, the measurements of sensors associated with the scientific instrument 2210). In some embodiments, the service local computing device 2230 may communicate with the scientific instrument 2210, the user local computing device 2220, or the remote computing device 2240 (e.g., via a direct communication pathway 2208 or via multiple “indirect” communication pathways 2208, as discussed above) to transmit data to the scientific instrument 2210, the user local computing device 2220, or the remote computing device 2240 (e.g., to update programmed instructions, such as firmware, in the scientific instrument 2210, to initiate the performance of test or calibration sequences in the scientific instrument 2210, to update programmed instructions, such as software, in the user local computing device 2220 or the remote computing device 2240). A user of the scientific instrument 2210 can utilize the scientific instrument 2210 or the user local computing device 2220 to communicate with the service local computing device 2230 to report a problem with the scientific instrument 2210 or the user local computing device 2220, to request a visit from a technician to improve the operation of the scientific instrument 2210, to order consumables or replacement parts associated with the scientific instrument 2210, or for other purposes.

The remote computing device 2240 can be a computing device (e.g., in accordance with any of the embodiments of the computing device 2100 discussed herein) that is remote from the scientific instrument 2210 or from the user local computing device 2220. In some embodiments, the remote computing device 2240 can be included in a datacenter or other large-scale server environment. In some embodiments, the remote computing device 2240 may include network-attached storage (e.g., as part of the storage device 2204). The remote computing device 2240 can store data generated by the scientific instrument 2210, perform analyses of the data generated by the scientific instrument 2210 (e.g., in accordance with programmed instructions), facilitate communication between the user local computing device 2220 and the scientific instrument 2210, or facilitate communication between the service local computing device 2230 and the scientific instrument 2210.

In some embodiments, one or more of the elements of the scientific instrument support system 2200 illustrated in FIG. 22 can be omitted. Further, in some embodiments, multiple ones of various ones of the elements of the scientific instrument support system 2200 of FIG. 22 may be present. For example, a scientific instrument support system 2200 can include multiple user local computing devices 2220 (e.g., different user local computing devices 2220 associated with different users or in different locations). In another example, a scientific instrument support system 2200 may include multiple scientific instruments 2210, all in communication with service local computing device 2230 and/or a remote computing device 2240; in such an embodiment, the service local computing device 2230 may monitor these multiple scientific instruments 2210, and the service local computing device 2230 may cause updates or other information may be “broadcast” to multiple scientific instruments 2210 at the same time. Different ones of the scientific instruments 2210 in a scientific instrument support system 2200 can be located close to one another (e.g., in the same room) or farther from one another (e.g., on different floors of a building, in different buildings, in different cities, etc.). In some embodiments, a scientific instrument 2210 can be connected to an Internet-of-Things (IoT) stack that allows for command and control of the scientific instrument 2210 through a web-based application, a virtual or augmented reality application, a mobile application, or a desktop application. Any of these applications can be accessed by a user operating the user local computing device 2220 in communication with the scientific instrument 2210 by the intervening remote computing device 2240. In some embodiments, a scientific instrument 2210 may be sold by the manufacturer along with one or more associated user local computing devices 2220 as part of a local scientific instrument computing unit 2212.

In some embodiments, different ones of the scientific instruments 2210 included in a scientific instrument support system 2200 may be different types of scientific instruments 2210; for example, one scientific instrument 2210 may be a mass spectrometer, while another scientific instrument 2210 may be a chromatograph or autosampler. In some such embodiments, the remote computing device 2240 or the user local computing device 2220 can combine data from different types of scientific instruments 2210 included in a scientific instrument support system 2200.

In various instances, machine learning algorithms or models can be implemented in any suitable way to facilitate any suitable aspects described herein. To facilitate some of the above-described machine learning aspects of various embodiments, consider the following discussion of artificial intelligence (AI). Various embodiments described herein can employ artificial intelligence to facilitate automating one or more features or functionalities. The components can employ various AI-based schemes for carrying out various embodiments/examples disclosed herein. In order to provide for or aid in the numerous determinations (e.g., determine, ascertain, infer, calculate, predict, prognose, estimate, derive, forecast, detect, compute) described herein, components described herein can examine the entirety or a subset of the data to which it is granted access and can provide for reasoning about or determine states of the system or environment from a set of observations as captured via events or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events or data.

Such determinations can result in the construction of new events or actions from a set of observed events or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes or systems (e.g., support vector machines, neural networks, expert systems, Bayesian belief networks, fuzzy logic, data fusion engines, and so on) in connection with performing automatic or determined action in connection with the claimed subject matter. Thus, classification schemes or systems can be used to automatically learn and perform a number of functions, actions, or determinations.

A classifier can map an input attribute vector, z=(z₁, z₂, z₃, z₄, zₙ), to a confidence that the input belongs to a class, as by f(z)=confidence(class). Such classification can employ a probabilistic or statistical-based analysis (e.g., factoring into the analysis utilities and costs) to determinate an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, or probabilistic classification models providing different patterns of independence, any of which can be employed. Classification as used herein also is inclusive of statistical regression that is utilized to develop models of priority.

In order to provide additional context for various embodiments described herein, FIG. 23 and the following discussion are intended to provide a brief, general description of a suitable computing environment 2300 in which the various embodiments of the embodiment described herein can be implemented. While the embodiments have been described above in the general context of computer-executable instructions that can run on one or more computers, those skilled in the art will recognize that the embodiments can be also implemented in combination with other program modules or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multi-processor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 23, the example environment 2300 for implementing various embodiments of the aspects described herein includes a computer 2302, the computer 2302 including a processing unit 2304, a system memory 2306 and a system bus 2308. The system bus 2308 couples system components including, but not limited to, the system memory 2306 to the processing unit 2304. The processing unit 2304 can be any of various commercially available processors. Dual microprocessors and other multi-processor architectures can also be employed as the processing unit 2304.

The system bus 2308 can be any of several types of bus structure that can further interconnect to a memory bus (with or without a memory controller), a peripheral bus, and a local bus using any of a variety of commercially available bus architectures. The system memory 2306 includes ROM 2310 and RAM 2312. A basic input/output system (BIOS) can be stored in a non-volatile memory such as ROM, erasable programmable read only memory (EPROM), EEPROM, which BIOS contains the basic routines that help to transfer information between elements within the computer 2302, such as during startup. The RAM 2312 can also include a high-speed RAM such as static RAM for caching data.

The computer 2302 further includes an internal hard disk drive (HDD) 2314 (e.g., EIDE, SATA), one or more external storage devices 2316 (e.g., a magnetic floppy disk drive (FDD) 2316, a memory stick or flash drive reader, a memory card reader, etc.) and a drive 2320, e.g., such as a solid state drive, an optical disk drive, which can read or write from a disk 2322, such as a CD-ROM disc, a DVD, a BD, etc. Alternatively, where a solid state drive is involved, disk 2322 would not be included, unless separate. While the internal HDD 2314 is illustrated as located within the computer 2302, the internal HDD 2314 can also be configured for external use in a suitable chassis (not shown). Additionally, while not shown in environment 2300, a solid state drive (SSD) could be used in addition to, or in place of, an HDD 2314. The HDD 2314, external storage device(s) 2316 and drive 2320 can be connected to the system bus 2308 by an HDD interface 2324, an external storage interface 2326 and a drive interface 2328, respectively. The interface 2324 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 2302, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 2312, including an operating system 2330, one or more application programs 2332, other program modules 2334 and program data 2336. All or portions of the operating system, applications, modules, or data can also be cached in the RAM 2312. The systems and methods described herein can be implemented utilizing various commercially available operating systems or combinations of operating systems.

Computer 2302 can optionally comprise emulation technologies. For example, a hypervisor (not shown) or other intermediary can emulate a hardware environment for operating system 2330, and the emulated hardware can optionally be different from the hardware illustrated in FIG. 23. In such an embodiment, operating system 2330 can comprise one virtual machine (VM) of multiple VMs hosted at computer 2302. Furthermore, operating system 2330 can provide runtime environments, such as the Java runtime environment or the .NET framework, for applications 2332. Runtime environments are consistent execution environments that allow applications 2332 to run on any operating system that includes the runtime environment. Similarly, operating system 2330 can support containers, and applications 2332 can be in the form of containers, which are lightweight, standalone, executable packages of software that include, e.g., code, runtime, system tools, system libraries and settings for an application.

Further, computer 2302 can be enable with a security module, such as a trusted processing module (TPM). For instance with a TPM, boot components hash next in time boot components, and wait for a match of results to secured values, before loading a next boot component. This process can take place at any layer in the code execution stack of computer 2302, e.g., applied at the application execution level or at the operating system (OS) kernel level, thereby enabling security at any level of code execution.

A user can enter commands and information into the computer 2302 through one or more wired/wireless input devices, e.g., a keyboard 2338, a touch screen 2340, and a pointing device, such as a mouse 2342. Other input devices (not shown) can include a microphone, an infrared (IR) remote control, a radio frequency (RF) remote control, or other remote control, a joystick, a virtual reality controller or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 2304 through an input device interface 2344 that can be coupled to the system bus 2308, but can be connected by other interfaces, such as a parallel port, an IEEE 1394 serial port, a game port, a USB port, an IR interface, a BLUETOOTH® interface, etc.

A monitor 2346 or other type of display device can be also connected to the system bus 2308 via an interface, such as a video adapter 2348. In addition to the monitor 2346, a computer typically includes other peripheral output devices (not shown), such as speakers, printers, etc.

The computer 2302 can operate in a networked environment using logical connections via wired or wireless communications to one or more remote computers, such as a remote computer(s) 2350. The remote computer(s) 2350 can be a workstation, a server computer, a router, a personal computer, portable computer, microprocessor-based entertainment appliance, a peer device or other common network node, and typically includes many or all of the elements described relative to the computer 2302, although, for purposes of brevity, only a memory/storage device 2352 is illustrated. The logical connections depicted include wired/wireless connectivity to a local area network (LAN) 2354 or larger networks, e.g., a wide area network (WAN) 2356. Such LAN and WAN networking environments are commonplace in offices and companies, and facilitate enterprise-wide computer networks, such as intranets, all of which can connect to a global communications network, e.g., the Internet.

When used in a LAN networking environment, the computer 2302 can be connected to the local network 2354 through a wired or wireless communication network interface or adapter 2358. The adapter 2358 can facilitate wired or wireless communication to the LAN 2354, which can also include a wireless access point (AP) disposed thereon for communicating with the adapter 2358 in a wireless mode.

When used in a WAN networking environment, the computer 2302 can include a modem 2360 or can be connected to a communications server on the WAN 2356 via other means for establishing communications over the WAN 2356, such as by way of the Internet. The modem 2360, which can be internal or external and a wired or wireless device, can be connected to the system bus 2308 via the input device interface 2344. In a networked environment, program modules depicted relative to the computer 2302 or portions thereof, can be stored in the remote memory/storage device 2352. It will be appreciated that the network connections shown are example and other means of establishing a communications link between the computers can be used.

When used in either a LAN or WAN networking environment, the computer 2302 can access cloud storage systems or other network-based storage systems in addition to, or in place of, external storage devices 2316 as described above, such as but not limited to a network virtual machine providing one or more aspects of storage or processing of information. Generally, a connection between the computer 2302 and a cloud storage system can be established over a LAN 2354 or WAN 2356 e.g., by the adapter 2358 or modem 2360, respectively. Upon connecting the computer 2302 to an associated cloud storage system, the external storage interface 2326 can, with the aid of the adapter 2358 or modem 2360, manage storage provided by the cloud storage system as it would other types of external storage. For instance, the external storage interface 2326 can be configured to provide access to cloud storage sources as if those sources were physically connected to the computer 2302.

The computer 2302 can be operable to communicate with any wireless devices or entities operatively disposed in wireless communication, e.g., a printer, scanner, desktop or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

FIG. 24 is a schematic block diagram of a sample computing environment 2400 with which the disclosed subject matter can interact. The sample computing environment 2400 includes one or more client(s) 2410. The client(s) 2410 can be hardware or software (e.g., threads, processes, computing devices). The sample computing environment 2400 also includes one or more server(s) 2430. The server(s) 2430 can also be hardware or software (e.g., threads, processes, computing devices). The servers 2430 can house threads to perform transformations by employing one or more embodiments as described herein, for example. One possible communication between a client 2410 and a server 2430 can be in the form of a data packet adapted to be transmitted between two or more computer processes. The sample computing environment 2400 includes a communication framework 2450 that can be employed to facilitate communications between the client(s) 2410 and the server(s) 2430. The client(s) 2410 are operably connected to one or more client data store(s) 2420 that can be employed to store information local to the client(s) 2410. Similarly, the server(s) 2430 are operably connected to one or more server data store(s) 2440 that can be employed to store information local to the servers 2430.

Various embodiments may be a system, a method, an apparatus or a computer program product at any possible technical detail level of integration. The computer program product can include a computer readable storage medium (or media) having computer readable program instructions thereon for causing a processor to carry out aspects of various embodiments. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network or a wireless network. The network can comprise copper transmission cables, optical transmission fibers, wireless transmission, routers, firewalls, switches, gateway computers or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of various embodiments can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform various aspects.

Various aspects are described herein with reference to flowchart illustrations or block diagrams of methods, apparatus (systems), and computer program products according to various embodiments. It will be understood that each block of the flowchart illustrations or block diagrams, and combinations of blocks in the flowchart illustrations or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart or block diagram block or blocks. These computer readable program instructions can also be stored in a computer readable storage medium that can direct a computer, a programmable data processing apparatus, or other devices to function in a particular manner, such that the computer readable storage medium having instructions stored therein comprises an article of manufacture including instructions which implement aspects of the function/act specified in the flowchart or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart or block diagram block or blocks.

The flowcharts and block diagrams in the Figures illustrate the architecture, functionality, and operation of possible implementations of systems, methods, and computer program products according to various embodiments. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer or computers, those skilled in the art will recognize that this disclosure also can or can be implemented in combination with other program modules. Generally, program modules include routines, programs, components, data structures, etc. that perform particular tasks or implement particular abstract data types. Moreover, those skilled in the art will appreciate that various aspects can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, or a computer. By way of illustration, both an application running on a server and the server can be a component. One or more components can reside within a process or thread of execution and a component can be localized on one computer or distributed between two or more computers. In another example, respective components can execute from various computer readable media having various data structures stored thereon. The components can communicate via local or remote processes such as in accordance with a signal having one or more data packets (e.g., data from one component interacting with another component in a local system, distributed system, or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. As used herein, the term “and/or” is intended to have the same meaning as “or.” Moreover, articles “a” and “an” as used in the subject specification and annexed drawings should generally be construed to mean “one or more” unless specified otherwise or clear from context to be directed to a singular form. As used herein, the terms “example” or “exemplary” are utilized to mean serving as an example, instance, or illustration. For the avoidance of doubt, the subject matter disclosed herein is not limited by such examples. In addition, any aspect or design described herein as an “example” or “exemplary” is not necessarily to be construed as preferred or advantageous over other aspects or designs, nor is it meant to preclude equivalent exemplary structures and techniques known to those of ordinary skill in the art.

The herein disclosure describes non-limiting examples. For ease of description or explanation, various portions of the herein disclosure utilize the term “each,” “every,” or “all” when discussing various examples. Such usages of the term “each,” “every,” or “all” are non-limiting. In other words, when the herein disclosure provides a description that is applied to “each,” “every,” or “all” of some particular object or component, it should be understood that this is a non-limiting example, and it should be further understood that, in various other examples, it can be the case that such description applies to fewer than “each,” “every,” or “all” of that particular object or component.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various non-limiting aspects are described in the following examples.

EXAMPLE 1: A device can comprise: an ion beam emitter that can be configured to perform milling of a cutface of a specimen via an ion beam; and a gas injector that can be configured to deliver a decomposed precursor to the cutface, wherein the ion beam can polymerize the decomposed precursor, thereby growing a polymer shield layer on the cutface during the milling.

EXAMPLE 2: The device of any preceding example can be implemented, wherein the decomposed precursor can comprise reactive ions or reactive neutrals that can be produced via excitation of a reactive gas.

EXAMPLE 3: The device of any preceding example can be implemented, wherein the gas injector can have an optical line-of-sight to the cutface, and wherein the gas injector can comprise: a reservoir for the reactive gas; a plasma reactor that can be configured to: receive from the reservoir the reactive gas; and excite the reactive gas via an electromagnetic field, thereby breaking the reactive gas into the reactive ions and the reactive neutrals; and a gas nozzle that can be configured to discharge the reactive neutrals to the cutface, wherein the ion beam can polymerize the reactive neutrals, thereby growing the polymer shield layer on the cutface during the milling.

EXAMPLE 4: The device of any preceding example can be implemented, wherein the gas injector can have no optical line-of-sight to the cutface, wherein the gas injector can be configured to discharge the reactive gas into an ion source of the ion beam emitter, wherein the ion source can excite the reactive gas during generation of the ion beam, thereby breaking the reactive gas into the reactive ions and the reactive neutrals, wherein the ion beam can carry the reactive ions to the cutface, and wherein the ion beam can polymerize the reactive ions, thereby growing the polymer shield layer on the cutface during the milling.

EXAMPLE 5: The device of any preceding example can be implemented, wherein the gas injector can discharge the reactive gas to the cutface, wherein the ion beam can excite the reactive gas, thereby breaking the reactive gas into the reactive ions and the reactive neutrals, and wherein the ion beam can polymerize the reactive ions and the reactive neutrals, thereby growing the polymer shield layer on the cutface during the milling.

EXAMPLE 6: The device of any preceding example can be implemented, wherein the reactive gas can comprise an organic fluoride gas.

EXAMPLE 7: The device of any preceding example can be implemented, wherein the reactive gas can comprise: tetraethylorthosilicate; tetramethylcyclotetrasiloxane; any other cyclosiloxane; or any other siloxane.

EXAMPLE 8: The device of any preceding example can be implemented, further comprising an etcher that can be configured to bathe the cutface in a dry or wet etchant, thereby removing the polymer shield layer, in response to cessation of the milling.

EXAMPLE 9: The device of any preceding example can be implemented, further comprising: an electron beam emitter that can be configured to emit an electron beam onto the cutface simultaneously with the ion beam, wherein the electron beam can assist the ion beam in polymerizing the decomposed precursor.

In various embodiments, any combination or combinations of examples 1-9 can be implemented.

EXAMPLE 10: A method can comprise: milling, by an ion beam emitter, a cutface of a specimen via an ion beam; and delivering, by a gas injector, a decomposed precursor to the cutface, wherein the ion beam can polymerize the decomposed precursor, thereby growing a polymer shield layer on the cutface during the milling.

EXAMPLE 11: The method of any preceding example can be implemented, wherein the decomposed precursor can comprise reactive ions or reactive neutrals that are produced via excitation of a reactive gas.

EXAMPLE 12: The method of any preceding example can be implemented, wherein the gas injector can have an optical line-of-sight to the cutface, and wherein the gas injector can comprise a reservoir for the reactive gas, a plasma reactor, and a gas nozzle, and further comprising: receiving, by the plasma reactor and from the reservoir, the reactive gas; exciting, by the plasma reactor, the reactive gas via an electromagnetic field, thereby breaking the reactive gas into the reactive ions and the reactive neutrals; and discharging, by the gas nozzle, the reactive neutrals to the cutface, wherein the ion beam can polymerize the reactive neutrals, thereby growing the polymer shield layer on the cutface during the milling.

EXAMPLE 13: The method of any preceding example can be implemented, wherein the gas injector can have no optical line-of-sight to the cutface, wherein the gas injector can comprise a reservoir for the reactive gas, and further comprising: receiving, by an ion source of the ion beam emitter and from the reservoir, the reactive gas; exciting, by the ion source, the reactive gas during generation of the ion beam, thereby breaking the reactive gas into the reactive ions and the reactive neutrals; and discharging, by the ion source, the ion beam and the reactive ions, wherein the ion beam can carry the reactive ions to the cutface, and wherein the ion beam can polymerize the reactive ions, thereby growing the polymer shield layer on the cutface during the milling.

EXAMPLE 14: The method of any preceding example can be implemented, wherein the gas injector can discharge the reactive gas to the cutface, wherein the ion beam can excite the reactive gas, thereby breaking the reactive gas into the reactive ions and the reactive neutrals, and wherein the ion beam can polymerize the reactive ions and the reactive neutrals, thereby growing the polymer shield layer on the cutface during the milling.

EXAMPLE 15: The method of any preceding example can be implemented, wherein the reactive gas can comprise an organic fluoride gas.

EXAMPLE 16: The method of any preceding example can be implemented, further comprising: bathing, by an etcher, the cutface in a dry or wet etchant, thereby removing the polymer shield layer, in response to cessation of the milling.

EXAMPLE 17: The method of any preceding example can be implemented, further comprising: emitting, by an electron beam emitter, an electron beam onto the cutface simultaneously with the ion beam, wherein the electron beam can assist the ion beam in polymerizing the decomposed precursor.

In various embodiments, any combination or combinations of examples 10-17 can be implemented.

EXAMPLE 18: A scientific instrument can comprise: a focused ion beam (FIB) system that can be configured to mill a lamella; and a gas injector system that can be configured to grow a polymer passivation layer on the lamella simultaneously as the FIB system mills the lamella, wherein the polymer passivation layer can protect vertical sidewalls of the lamella from milling.

EXAMPLE 19: The scientific instrument of any preceding example can be implemented, wherein the FIB system can be configured to mill the lamella by bombarding the lamella with an ion beam, wherein the gas injector system can be configured to transport a decomposed precursor to the lamella as the FIB system mills the lamella, and wherein the ion beam can polymerize the decomposed precursor, thereby growing the polymer passivation layer as the FIB system mills the lamella.

EXAMPLE 20: The scientific instrument of any preceding example can be implemented, wherein the decomposed precursor can comprise reactive neutrals or reactive ions produced by breaking down an organic fluoride gas.

In various embodiments, any combination or combinations of examples 18-20 can be implemented.

In various embodiments, any combination or combinations of examples 1-20 can be implemented.

What is claimed is:

1. A device, comprising:
an ion beam emitter that is configured to perform milling of a cutface of a specimen via an ion beam; and
a gas injector that is configured to deliver a decomposed precursor to the cutface, wherein the ion beam polymerizes the decomposed precursor, thereby growing a polymer shield layer on the cutface during the milling.

2. The device of claim 1, wherein the decomposed precursor comprises reactive ions or reactive neutrals that are produced via excitation of a reactive gas.

3. The device of claim 2, wherein the gas injector has an optical line-of-sight to the cutface, and wherein the gas injector comprises:
a reservoir for the reactive gas;
a plasma reactor that is configured to:
receive from the reservoir the reactive gas; and
excite the reactive gas via an electromagnetic field, thereby breaking the reactive gas into the reactive ions and the reactive neutrals; and
a gas nozzle that is configured to discharge the reactive neutrals to the cutface, wherein the ion beam polymerizes the reactive neutrals, thereby growing the polymer shield layer on the cutface during the milling.

4. The device of claim 2, wherein the gas injector does not have an optical line-of-sight to the cutface, wherein the gas injector is configured to discharge the reactive gas into an ion source of the ion beam emitter, wherein the ion source excites the reactive gas during generation of the ion beam, thereby breaking the reactive gas into the reactive ions and the reactive neutrals, wherein the ion beam carries the reactive ions to the cutface, and wherein the ion beam polymerizes the reactive ions, thereby growing the polymer shield layer on the cutface during the milling.

5. The device of claim 2, wherein the gas injector discharges the reactive gas to the cutface, wherein the ion beam excites the reactive gas, thereby breaking the reactive gas into the reactive ions and the reactive neutrals, and wherein the ion beam polymerizes the reactive ions and the reactive neutrals, thereby growing the polymer shield layer on the cutface during the milling.

6. The device of claim 2, wherein the reactive gas comprises an organic fluoride gas.

7. The device of claim 2, wherein the reactive gas comprises: tetraethylorthosilicate; tetramethylcyclotetrasiloxane; any other cyclosiloxane; or any other siloxane.

8. The device of claim 1, further comprising an etcher that is configured to bathe the cutface in a dry or wet etchant, thereby removing the polymer shield layer, in response to cessation of the milling.

9. The device of claim 1, wherein the device further comprises:
an electron beam emitter that is configured to emit an electron beam onto the cutface simultaneously with the ion beam, wherein the electron beam assists the ion beam in polymerizing the decomposed precursor.

10. A method, comprising:
milling, by an ion beam emitter, a cutface of a specimen via an ion beam; and
delivering, by a gas injector, a decomposed precursor to the cutface, wherein the ion beam polymerizes the decomposed precursor, thereby growing a polymer shield layer on the cutface during the milling.

11. The method of claim 10, wherein the decomposed precursor comprises reactive ions or reactive neutrals that are produced via excitation of a reactive gas.

12. The method of claim 11, wherein the gas injector has an optical line-of-sight to the cutface, and wherein the gas injector comprises a reservoir for the reactive gas, a plasma reactor, and a gas nozzle, and further comprising:
receiving, by the plasma reactor and from the reservoir, the reactive gas;
exciting, by the plasma reactor, the reactive gas via an electromagnetic field, thereby breaking the reactive gas into the reactive ions and the reactive neutrals; and
discharging, by the gas nozzle, the reactive neutrals to the cutface, wherein the ion beam polymerizes the reactive neutrals, thereby growing the polymer shield layer on the cutface during the milling.

13. The method of claim 11, wherein the gas injector does not have an optical line-of-sight to the cutface, and wherein the gas injector comprises a reservoir for the reactive gas, and further comprising:
receiving, by an ion source of the ion beam emitter and from the reservoir, the reactive gas;
exciting, by the ion source, the reactive gas during generation of the ion beam, thereby breaking the reactive gas into the reactive ions and the reactive neutrals; and
discharging, by the ion beam emitter, the ion beam and the reactive ions, wherein the ion beam carries the reactive ions to the cutface, and wherein the ion beam polymerizes the reactive ions, thereby growing the polymer shield layer on the cutface during the milling.

14. The method of claim 11, wherein the gas injector discharges the reactive gas to the cutface, wherein the ion beam excites the reactive gas, thereby breaking the reactive gas into the reactive ions and the reactive neutrals, and wherein the ion beam polymerizes the reactive ions and the reactive neutrals, thereby growing the polymer shield layer on the cutface during the milling.

15. The method of claim 11, wherein the reactive gas comprises an organic fluoride gas.

16. The method of claim 10, further comprising:
bathing, by an etcher, the cutface in a dry or wet etchant, thereby removing the polymer shield layer, in response to cessation of the milling.

17. The method of claim 10, further comprising:
emitting, by an electron beam emitter, an electron beam onto the cutface simultaneously with the ion beam, wherein the electron beam assists the ion beam in polymerizing the decomposed precursor.

18. A scientific instrument, comprising:
a focused ion beam (FIB) system that is configured to mill a lamella; and
a gas injector system that is configured to grow a polymer passivation layer on the lamella simultaneously as the FIB system mills the lamella, wherein the polymer passivation layer protects vertical sidewalls of the lamella from milling.

19. The scientific instrument of claim 18, wherein the FIB system is configured to mill the lamella by bombarding the lamella with an ion beam, wherein the gas injector system is configured to transport a decomposed precursor to the lamella as the FIB system mills the lamella, and wherein the ion beam polymerizes the decomposed precursor, thereby growing the polymer passivation layer as the FIB system mills the lamella.

20. The scientific instrument of claim 19, wherein the decomposed precursor comprises reactive neutrals or reactive ions produced by breaking down an organic fluoride gas.
